(19) United States
(12) Patent Application Publication
(10) Pub. No.: US 2025/0393264 A1
(43) Pub. Date: Dec. 25, 2025

(54) THIN-FILM TRANSISTOR, MANUFACTURING METHOD THEREOF, AND ELECTRONIC DEVICE INCLUDING THE THIN-FILM TRANSISTOR

(71) Applicants: Samsung Display Co., Ltd., Yongin-si (KR); Industry-University Cooperation Foundation Hanyang University ERICA Campus, Ansan-si (KR)

(72) Inventors: Joon Seok PARK, Yongin-si (KR); Saeroonter OH, Ansan-si (KR); Hyoung Do KIM, Yongin-si (KR); MINGEUN YUN, Ansan-si (KR); Taeho LEE, Ansan-si (KR); Sun Hee LEE, Yongin-si (KR)

(21) Appl. No.: 19/208,352

(22) Filed: May 14, 2025

(30) Foreign Application Priority Data
Jun. 25, 2024 (KR) 10-2024-0083194
Jul. 11, 2024 (KR) 10-2024-0091577

(51) Int. Cl. H10D 62/10; H10D 30/01; H10D 30/67

(52) U.S. Cl. CPC H10D 62/117; H10D 30/024; H10D 30/6736

(57) ABSTRACT

A thin-film transistor includes a substrate; a first electrode on the substrate; a first gate electrode on the first electrode; a first buffer layer between the first electrode and the first gate electrode; a first gate insulating layer on the first gate electrode; a second electrode on the first gate insulating layer; an active layer being extended in a horizontal direction along a bottom surface and in a normal direction along an internal wall of a first opening penetrating the first gate electrode, the first buffer layer, the first gate insulating layer, and the second electrode, and connected to the first electrode and the second electrode; a second gate electrode being extended along a surface of the active layer; and a second gate insulating layer between the active layer and the second gate electrode.

### CROSS-REFERENCE TO RELATED APPLICATION

The present application claims priority to and the benefit of Korean Patent Application No. 10-2024-0091577, filed on Jul. 11, 2024, in the Korean Intellectual Property Office, and Korean Patent Application No. 10-2024-0083194, filed on Jun. 25, 2024, in the Korean Intellectual Property Office, the entire contents of both of which are incorporated herein by reference.

### BACKGROUND

### 1. Field

Embodiments of the present disclosure described herein are related to a thin-film transistor, a manufacturing method thereof, and an electronic device including the thin-film transistor.

### 2. Description of the Related Art

Thin-film transistors (TFT) are used in one or more suitable fields, for example, as switching and driving elements in display devices such as an organic light emitting diode (OLED) display and/or an electrophoretic display.

As the sizes of the displays increase, there is a growing need or desire to develop thin-film transistors that may operate at higher rates. Hence, many researchers are working on enhancing (e.g., improving) carrier mobility and switching rates by enhancing (e.g., improving) structures of the thin-film transistors and their external processing.

The information disclosed in this Background section is intended to enhance understanding of the background of the disclosure and therefore it may contain information that does not constitute prior art.

### SUMMARY

Aspects according to one or more embodiments of the present disclosure are directed toward a thin-film transistor in which gate electrodes are arranged on each side of a channel extending in a normal (e.g., perpendicular) direction (e.g., to a substrate), and a manufacturing method of the thin-film transistor.

One or more embodiments of the present disclosure includes a thin-film transistor including a substrate; a first electrode arranged on the substrate; a first gate electrode arranged on the first electrode; a first buffer layer arranged between the first electrode and the first gate electrode; a first gate insulating layer arranged on the first gate electrode; a second electrode arranged on the first gate insulating layer; an active layer being extended in a horizontal direction along a bottom surface and in a normal (e.g., perpendicular) direction along an internal wall of a first opening penetrating the first gate electrode, the first buffer layer, the first gate insulating layer, and the second electrode, and connected to the first electrode and the second electrode; a second gate electrode being extended along a surface of the active layer; and a second gate insulating layer arranged between the active layer and the second gate electrode, wherein the active layer being extended in the normal (e.g., perpendicular) direction along the internal wall of the first opening overlaps the first gate electrode and the second gate electrode in the horizontal direction.

In one or more embodiments, the first opening may include a bottom surface defined by an upper surface of the first electrode, and an internal wall defined by the first gate insulating layer and the second electrode, and the active layer may include a first horizontal portion being extended in a horizontal direction along the bottom surface of the first opening, a normal (e.g., perpendicular) portion being extended in the normal (e.g., perpendicular) direction along the internal wall of the first opening, and a second horizontal portion being extended in the horizontal direction along an upper surface of the second electrode.

In one or more embodiments, the thin-film transistor may further include a second buffer layer arranged between the first gate electrode and the first gate insulating layer, wherein the first buffer layer and the second buffer layer may be around (e.g., surround) the first opening.

In one or more embodiments, the normal (e.g., perpendicular) portion of the active layer may include a first portion overlapping the first buffer layer in the horizontal direction, a second portion overlapping the first gate electrode in the horizontal direction and not overlapping the second gate electrode in the horizontal direction, a third portion overlapping the first gate electrode and the second gate electrode in the horizontal direction, and a fourth portion overlapping the first gate insulating layer and the second buffer layer in the horizontal direction, the first portion, the second portion, the third portion, and the fourth portion may be continuously arranged in the normal (e.g., perpendicular) direction, and a thickness of the third portion may be greater than the thickness of each of the first portion, the second portion, and fourth portion.

In one or more embodiments, a sum of the thickness of the first portion, the thickness of the second portion, and the thickness of the fourth portion may be less than the thickness of the third portion.

In one or more embodiments, the thicknesses of the first horizontal portion, the normal (e.g., perpendicular) portion, and the second horizontal portion of the active layer may be equal (e.g., substantially equal) to each other.

In one or more embodiments, the active layer may include an oxide semiconductor material, and the oxide semiconductor material may include at least one of In, Ga, Zn, or Sn.

In one or more embodiments, the active layer may include a first active layer being extended along the upper surface of the second electrode and the bottom surface and the internal wall of the first opening, and a second active layer arranged between the first active layer and the second gate insulating layer, a first material included in the first active layer and the first material included in the second active layer may have different composition ratios, and the first material may be at least one of In, Ga, Zn, or Sn.

In one or more embodiments, the first active layer and the second active layer may have different thicknesses.

In one or more embodiments, the thin-film transistor may further include a first transparent electrode arranged between the first electrode and the first horizontal portion of the active layer, and a second transparent electrode arranged between the second electrode and the second horizontal portion of the active layer.

In one or more embodiments, the first transparent electrode may cover the upper surface of the first electrode, and the second transparent electrode may cover a portion of the upper surface of the second electrode.

In one or more embodiments, the thin-film transistor may include a second opening penetrating the second gate electrode in the first opening and defined by the upper surface of the second gate insulating layer and the lateral surface of the second gate electrode.

In one or more embodiments, the thin-film transistor may include a second opening penetrating the first horizontal portion of the active layer, the second gate insulating layer, and the second gate electrode in the first opening, and defined by the upper surface of the first electrode, a lateral surface of the first horizontal portion of the active layer, a lateral surface of the second gate insulating layer, and a lateral surface of the second gate electrode.

In one or more embodiments, the first opening may have a width less than the width of the first electrode.

In one or more embodiments, the width of the first opening may be in a range of about 1.5 μm to about 3 μm.

In one or more embodiments, the first opening may have a circular, oval, or polygonal shape in a plan view.

According to one or more embodiments of the present disclosure, a method for manufacturing a thin-film transistor may include: forming a first electrode arranged on a substrate; forming a first buffer layer on the first electrode; forming a first gate electrode on the first buffer layer; removing a portion of the first gate electrode and a portion of the first buffer layer to expose the first electrode; sequentially forming a first gate insulating layer and a second electrode on the first electrode, the first gate electrode, and the first buffer layer being exposed by the first gate electrode and the first buffer layer; forming an opening for exposing the first electrode by removing a portion of the first gate insulating layer and a portion of the second electrode; forming an active layer being extended along an upper surface of the second electrode and a bottom surface and an internal wall of the opening; forming a second gate insulating layer being extended along a surface of the active layer and the upper surface of the second electrode; and forming a second gate electrode being extended along the surface of the second gate insulating layer.

In one or more embodiments, the method may further include forming a second buffer layer on the first gate electrode before removing a portion of the first gate electrode and a portion of the first buffer layer, wherein the removing of a portion of the first gate electrode and a portion of the first buffer layer may include removing a portion of the first buffer layer and a portion of the second buffer layer together with a portion of the first gate electrode and a portion of the first buffer layer.

In one or more embodiments, the opening may include a bottom surface defined by the upper surface of the first electrode, and an internal wall defined by the first gate insulating layer and the second electrode.

In one or more embodiments, an electronic device may include a thin-film transistor comprising a substrate; a first electrode arranged on the substrate; a first gate electrode arranged on the first electrode; a first buffer layer arranged between the first electrode and the first gate electrode; a first gate insulating layer arranged on the first gate electrode; a second electrode arranged on the first gate insulating layer; an active layer being extended in a horizontal direction along a bottom surface and in a normal (e.g., perpendicular) direction along an internal wall of a first opening penetrating the first gate electrode, the first buffer layer, the first gate insulating layer, and the second electrode, and connected to the first electrode and the second electrode; a second gate electrode being extended along a surface of the active layer; and a second gate insulating layer arranged between the active layer and the second gate electrode, wherein the active layer being extended in the normal (e.g., perpendicular) direction along the internal wall of the first opening overlaps the first gate electrode and the second gate electrode in the horizontal direction.

According to one or more embodiments, the thin-film transistor may be provided with increased efficiency of power consumption by increasing carrier mobility, adjustability of threshold voltage, and switching rates.

### BRIEF DESCRIPTION OF THE DRAWINGS

FIG. 1 shows a top plan view of a display device according to one or more embodiments.

FIG. 2 shows a block diagram of a display device according to one or more embodiments.

FIG. 3 shows a circuit diagram of a display device according to one or more embodiments.

FIG. 4 shows a cross-sectional view of a thin-film transistor according to one or more embodiments.

FIG. 5 shows a top plan view of a region corresponding to a line A-A′ of FIG. 4.

FIG. 6 shows a partially enlarged view of a region P of FIG. 4.

FIG. 7-FIG. 10 show cross-sectional views of thin-film transistors according to several embodiments.

FIG. 11 shows a cross-sectional view of a display device including a thin-film transistor according to one or more embodiments.

FIG. 12-FIG. 18 show sequential cross-sectional views of a method for manufacturing a thin-film transistor according to one or more embodiments.

FIG. 19 is a block diagram of an electronic device according to one or more embodiments.

FIG. 20 shows schematic diagrams of electronic devices according to one or more embodiments.

### DETAILED DESCRIPTION

The present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure.

The drawings and description are to be regarded as illustrative in nature and not restrictive, and like reference numerals designate like elements throughout, and duplicative descriptions thereof may not be provided the specification.

The size and thickness of each configuration shown in the drawings are arbitrarily shown for better understanding and ease of description, but the present disclosure is not limited thereto. In the drawings, the thicknesses of layers, films, panels, regions, and/or the like, are enlarged for clarity. The thicknesses of layers, films, panels, regions, and/or the like, are exaggerated for clarity.

It should be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present. The word “on” or “above” refers to being positioned on or below the object portion, and does not necessarily refer to being positioned on the upper side of the object portion based on a gravitational direction.

Unless explicitly stated to the contrary, the word “comprise,” and variations such as “comprises” or “comprising,” should be understood to imply the inclusion of stated elements but not the exclusion of any other elements.

The phrase “on a plane” refers to viewing the object portion from the top, and the phrase “on a cross-section” refers to viewing a cross-section of which the object portion is vertically cut from the side.

In the present specification, “including A or B”, “A and/or B”, etc., represents A or B, or A and B.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b or c”, “at least one selected from a, b and c”, etc., may indicate only a, only b, only c, both (e.g., simultaneously) a and b, both (e.g., simultaneously) a and c, both (e.g., simultaneously) b and c, all of a, b, and c, or variations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

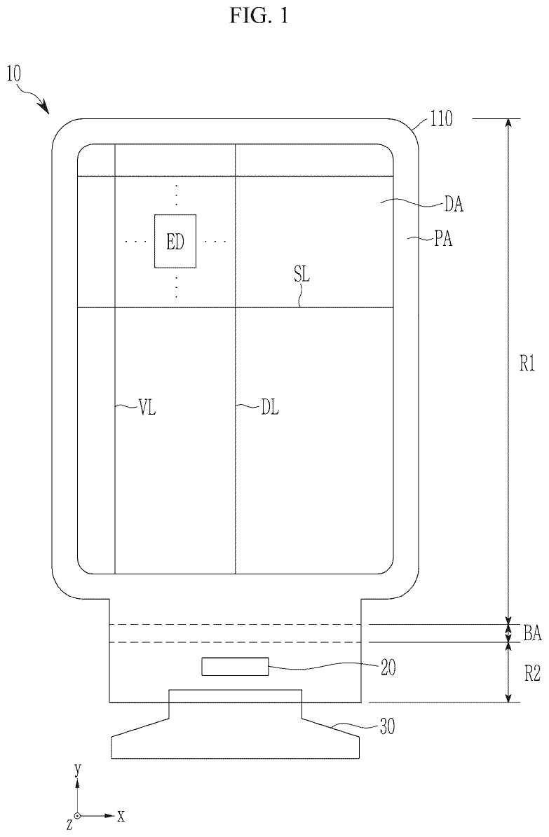

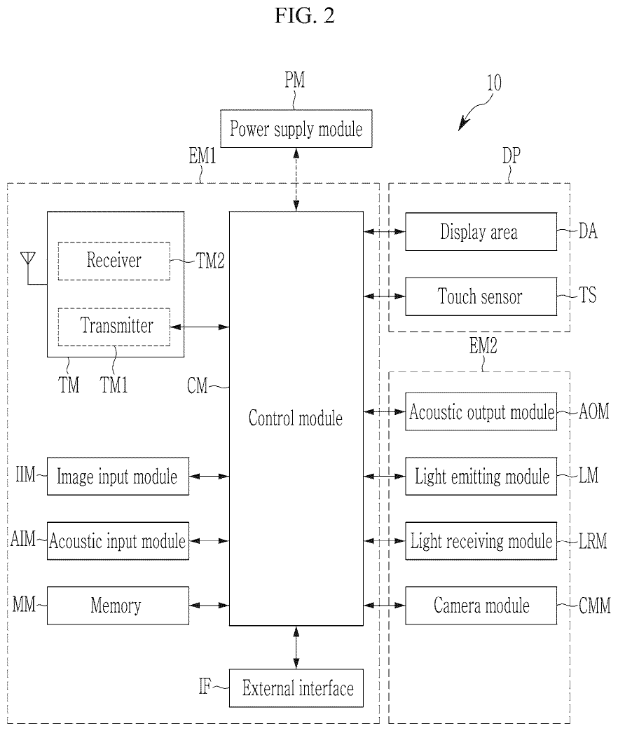

A display device according to one or more embodiments will now be described in more detail with reference to FIG. 1 and FIG. 2.

FIG. 1 shows a top plan view of a display device according to one or more embodiments. FIG. 2 shows a block diagram of a display device according to one or more embodiments.

Referring to FIG. 1, the display device 10 may be configured to display videos or images (e.g., still images) and may be used as a displaying screen for one or more suitable types (kinds) of products (e.g., electronic devices) such as televisions, laptops, monitors, billboards, or Internet of Things (IoT) in addition to portable electronic devices such as mobile phones, smart phones, tablet PCs, smart watches, watch phones, mobile communication terminals, digital organizers, electronic books, portable multimedia players (PMP), global positioning systems, and/or ultra-mobile PCs (UMPC).

The display device 10 may be used in wearable devices (e.g., electronic devices), such as smart watches, watch phones, glass-type (kind) displays, and/or head mounted displays (HMD). The display device 10 may be used as an electronic device, e.g., a dashboard of a vehicle, a center information display (CID) arranged on a center fascia or a dashboard of a vehicle, a room mirror display replacing a side-view mirror of a vehicle, and/or a display arranged on a rear surface of a front seat for entertainment for a back seat of a vehicle. For better comprehension and ease of description, FIG. 1 shows that the display device 10 is used as a smartphone, but is not limited thereto.

The display device 10 may be one of an organic light emitting display device, a plasma display device, a field emission display, a quantum dot emissive display device, a micro-LED display device, and a liquid crystal display. For example, the display device 10 may be an organic light emitting display device, but one or more embodiments is not limited thereto.

The display device 10 may be a flexible, stretchable, foldable, bendable, or rollable display device.

The display device 10 may include a substrate 110 including a display area DA and a peripheral area PA arranged near the display area DA, light emitting devices ED arranged in the display area DA of the substrate 110, scan lines SL connected to the light emitting devices ED, data lines DL, and driving voltage lines VL.

The substrate 110 may be made of a flexible, stretchable, foldable, bendable, or rollable material.

The display area DA may be configured to display images and may have a substantially quadrangular shape. For example, the display area DA may have a rectangular shape including two sides being extended in a first direction X and two sides being extended in a second direction Y, and a corner portion may be chamfered in a round shape. However, this is an example, and the shape of the display area DA may be modifiable in many ways according to uses of the display device.

Light emitting devices ED may be arranged in a set or predetermined form in the display area DA. For example, the light emitting devices ED may be arranged in a row direction and a column direction. However, this is an example, and disposition of the light emitting devices ED may be modifiable in many ways.

Signal lines or voltage lines electrically connected to the light emitting devices ED arranged in the display area DA and applying signals or driving voltages.

The signal lines or the voltage lines may include scan lines SL for transmitting scan signals to the light emitting devices ED, data lines DL for transmitting data signals to the light emitting devices ED, and driving voltage lines VL for transmitting driving voltages to the light emitting devices ED. Each of the light emitting devices ED may be connected to at least one transistor and capacitor.

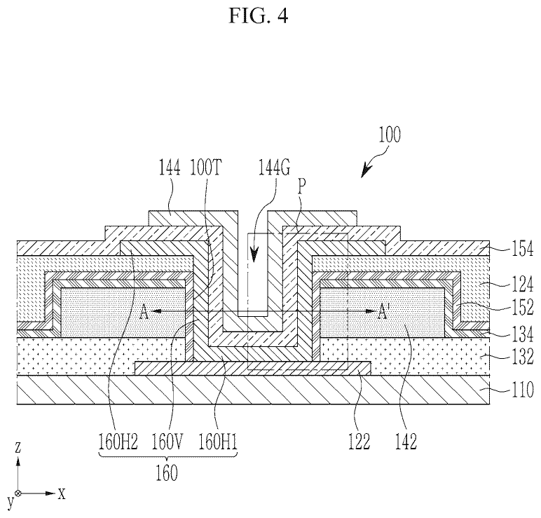

The transistor will be described in more detail later with reference to FIG. 4 to FIG. 6.

The scan lines SL may be extended in the first direction X in the display area DA, and the data lines DL and the driving voltage lines VL may be extended in the second direction Y, but are not limited thereto. For example, the scan lines SL and the data lines DL may be orthogonal to each other.

A touch sensor for sensing contact and/or non-contact touches of a user may be arranged in the display area DA.

The peripheral area PA may be arranged outside the display area DA and may be around (e.g., surround) the display area DA.

The peripheral area PA may include a first region R1 around (e.g., surrounding) the display area DA, a second region R2 spaced and/or apart (e.g., spaced apart or separated) from one edge of the first region R1, and a bending area BA arranged between the first region R1 and the second region R2. For example, the bending area BA may be extended from a lower edge of the first region R1, and the second region R2 may be extended from the bending area BA. For example, the bending area BA may be extended from a lower edge of the first region R1 to an upper edge of the second region R2.

The substrate 110 may be bent in the bending area BA or along the bending area BA. The bending area BA may be extended in the first direction X. When the substrate 110 is bent along the bending area BA, the second region R2 may be arranged on a rear surface of the first region R1. For example, the second region R2 overlaps the first region R1 while the substrate 110 is bent.

The display device 10 may further include a driver for generating and transmitting signals for driving display devices such as a driving circuit chip 20, a flexible printed circuit 30, and a scan driver arranged in the peripheral area PA.

The driving circuit chip 20 and the flexible printed circuit 30 may be arranged in the second region R2. The driving circuit chip 20 may be connected to the light emitting device ED arranged in the display area DA via wiring, and may be configured to transmit one or more suitable signals. For example, the driving circuit chip 20 may be connected to the data line DL being extended to the peripheral area PA from the display area DA and may be configured to transmit data signals.

The flexible printed circuit 30 may be attached to one edge of the substrate 110. For example, the flexible printed circuit 30 may be attached to an end portion of the second region R2. The flexible printed circuit 30 may be made of a flexible material, and a circuit for controlling driving of the display device may be designed.

In one or more embodiments, a scan driver may be arranged in the first region R1, and may be arranged in the first region R1 arranged near a left edge and/or a right edge of the display area DA. The scan driver may be connected to the light emitting device ED through the scan lines SL and may be configured to transmit scan signals. The respective light emitting devices ED may receive data signals at set or predetermined timings according to the scan signals.

Signal lines for transmitting one or more suitable control signals, driving voltages, and common voltages may be arranged in the peripheral area PA. The signal lines may be connected to the flexible printed circuit 30, and may receive set or predetermined signals from the flexible printed circuit 30. For example, the driving voltage line VL being extended to the peripheral area PA from the display area DA may be connected to the flexible printed circuit 30 and may receive set or predetermined signals from the flexible printed circuit 30.

Referring to FIG. 2, the display device 10 may include a display panel DP, a power supply module PM, a first electronic module EM1, and a second electronic module EM2. The display panel DP, the power supply module PM, the first electronic module EM1, and the second electronic module EM2 may be electrically connected to each other. FIG. 2 shows a display pixel and a touch sensor TS arranged in the display area DA in the configuration of the display panel DP.

The power supply module PM may supply power for the general operation of the display device 10. The power supply module PM may include a battery module.

The first electronic module EM1 and the second electronic module EM2 may include one or more suitable functional modules for operating the display device 10. The first electronic module EM1 may be mounted on a motherboard electrically connected to the display panel DP, or may be mounted on an additional substrate and may be electrically connected to the motherboard through a connector.

The first electronic module EM1 may include a control module CM, a wireless communication module TM, an image input module IIM, an acoustic input module AIM, a memory MM, and an external interface IF. Some of the modules may not be mounted on the motherboard, and may be electrically connected to the motherboard through the flexible printed circuit 30 connected thereto.

The control module CM may control the general operation of the display device 10. The control module CM may be a microprocessor. For example, the control module CM activates/deactivates the display panel DP. The control module CM may control the modules such as the image input module IIM or the acoustic input module AIM based on the touch signal received from the display panel DP.

The wireless communication module TM may be configured to transmit/receive radio signals to/from other terminals by using Bluetooth or Wi-Fi lines. The wireless communication module TM may be configured to transmit/receive voice signals by using general communication lines. The wireless communication module TM includes a transmitter TM1 for modulating signals and transmitting the signals, and a receiver TM2 for receiving the signals and demodulating the signals.

The image input module IIM may process video signals to convert them into image data displayable on the display panel DP. The acoustic input module AIM may receive external acoustic signals by a microphone in a recording mode or a voice recognition mode and may convert them into electrical voice data.

The external interface IF may function as an interface connected to an external charger, a wired/wireless data port, and a card socket (e.g., a memory card, a SIM/UIM card), and/or the like.

1 The second electronic module EM2 may include an acoustic output module AOM, a light emitting module LM, a light receiving module LRM, and a camera module CMM, and at least some thereof may be arranged as optical elements ES on a rear surface of the display panel DP. The optical elements ES may include the light emitting module LM, the light receiving module LRM, and the camera module CMM. The second electronic module EM2 may be mounted on the motherboard, may be mounted on an additional substrate and electrically connected to the display panel DP through a connector, or may be electrically connected to the first electronic module EM1.

The acoustic output module AOM may convert the acoustic data received from the wireless communication module TM or the acoustic data stored in the memory MM and may output them to the outside.

The light emitting module LM may generate light and may output the light. The light emitting module LM may output infrared rays. For example, the light emitting module LM may include LED devices. For example, the light receiving module LRM may sense the infrared rays. The light receiving module LRM may be activated if (e.g., when) sensing the infrared rays of greater than a set or predetermined level. The light receiving module LRM may include a CMOS sensor. When the infrared rays generated by the light emitting module LM are output, the infrared rays may be reflected by an external subject (e.g., a user's finger or face), and the reflected infrared rays may be input to the light receiving module LRM. The camera module CMM may be configured to image external images.

In one or more embodiments, the optical element ES may additionally include a photosensor or a heat sensor. The optical element ES may sense the external subject received through the front surface or may provide sound signals such as voice to the outside. The optical element ES may include a plurality of components, and is not limited to one or more embodiments. For example, the optical elements ES may include one or more components in addition to the photosensor and/or the heat sensor.

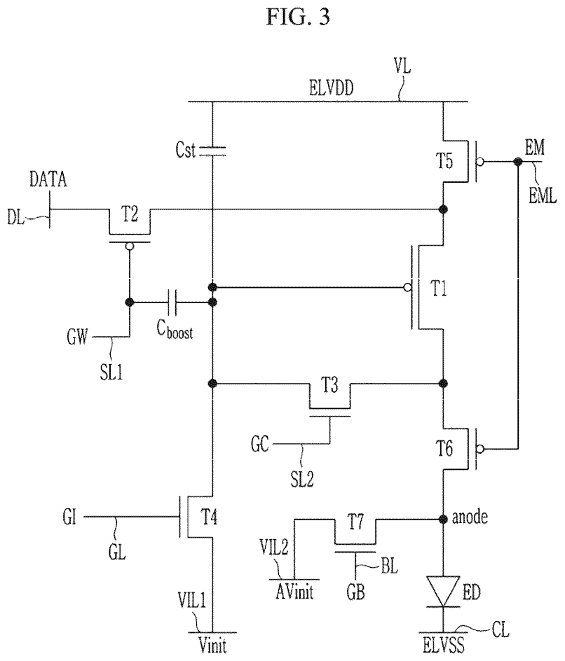

FIG. 3 shows a circuit diagram of a display device according to one or more embodiments.

FIG. 3 shows a circuit diagram of a pixel included in a display device 10 according to one or more embodiments.

One pixel may include transistors T1, T2, T3, T4, T5, T6, and T7, a storage capacitor Cst, a boost capacitor C_{boost}, and a light emitting device ED connected to wires VIL1, VIL2, SL1, SL2, GL, BL, EML, DL, VL, and CL.

The transistors and the capacitors excluding (e.g., not including) the light emitting device ED may include a pixel circuit portion. Depending on embodiments, the boost capacitor C_{boost} may not be provided. The transistors T1, T2, T3, T4, T5, T6, and T7 may be divided into polycrystalline semiconductor transistors including a polycrystalline semiconductor and oxide semiconductor transistors including an oxide semiconductor, and the polycrystalline semiconductor transistors may include the driving transistor T1, the second transistor T2, the fifth transistor T5, and the sixth transistor T6, and the oxide semiconductor transistor may include the third transistor T3, the fourth transistor T4, and the seventh transistor T7.

The wires VIL1, VIL2, SL1, SL2, GL, BL, EML, DL, VL, and CL may be connected to one pixel. The wires may include the first initialization voltage line VIL1, the second initialization voltage line VIL2, the first scan line SL1, the second scan line SL2, the initialization control line GL, the bypass control line BL, the light emission control line EML, the data line DL, the driving voltage line VL, and the common voltage line CL.

The first scan line SL1 is connected to a scan driver and is configured to transmit the first scan signal GW to the second transistor T2 and the seventh transistor T7. A voltage with opposite polarity to the voltage applied to the first scan line SL1 may be applied to the second scan line SL2 at the same timing (e.g., simultaneously) as the signal of the first scan line SL1. For example, if (e.g., when) the voltage with negative polarity is applied to the first scan line SL1, the voltage with positive polarity may be applied to the second scan line SL2. The second scan line SL2 is configured to transmit the second scan signal GC to the third transistor T3. The initialization control line GL is configured to transmit the initialization control signal GI to the fourth transistor T4, the light emission control line EML is configured to transmit the light emission control signal EM to the fifth transistor T5 and the sixth transistor T6, and the bypass control line BL is configured to transmit the bypass control signal GB to the seventh transistor T7. The bypass control signal GB may be applied as the voltage with opposite polarity at the same timing (e.g., simultaneously) as the first scan signal GW, and may have the same signal as the second scan signal GC.

The data line DL is configured to transmit the data voltage DATA generated by a data driver so a size of a light emitting current transmitted to the light emitting device ED may change and luminance of light emitted by the light emitting device ED may change. The driving voltage line VL may apply a driving voltage ELVDD. The first initialization voltage line VIL1 may be configured to transmit a first initialization voltage Vinit, and the second initialization voltage line VIL2 may be configured to transmit a second initialization voltage AVinit. The common voltage line CL may apply a common voltage ELVSS to a cathode of the light emitting device ED. In one or more embodiments, constant voltages may be applied to the driving voltage line VL, the first and second initialization voltage lines VIL1 and VIL2, and the common voltage line CL. For example, the voltages applied to the driving voltage line VL, the first and second initialization voltage lines VIL1 and VIL2, and the common voltage line CL may be equal to each other.

The driving transistor T1 (or a first transistor) may be a p-type (kind) transistor and may have a silicon semiconductor (or a polycrystalline semiconductor) as a semiconductor layer. The size of the light emitting current output to the anode of the light emitting device ED may be controlled or selected according to the size of the voltage (i.e., the voltage stored in the storage capacitor Cst) at a gate electrode of the driving transistor T1. Brightness of the light emitting device ED is controlled or selected according to the size of the light emitting current output to the anode of the light emitting device ED so luminance of the light emitting device ED may be controlled or selected according to the data voltage DATA applied to the pixel. To this end, a first electrode of the driving transistor T1 may be arranged to receive the driving voltage ELVDD, may pass through the fifth transistor T5 and may be connected to the driving voltage line VL. The first electrode of the driving transistor T1 may be connected to a second electrode of the second transistor T2 and may receive the data voltage DATA. The second electrode of the driving transistor T1 may output the light emitting current to the light emitting device ED, may pass through the sixth transistor T6 (or an output control transistor), and may be connected to the anode of the light emitting device ED. The second electrode of the driving transistor T1 may be connected to the third transistor T3, and may be configured to transmit the data voltage DATA applied to the first electrode to the third transistor T3. The gate electrode of the driving transistor T1 may be connected to one electrode (or a second storage electrode) of the storage capacitor Cst. Hence, the voltage at the gate electrode of the driving transistor T1 may change according to the voltage stored in the storage capacitor Cst, and the light emitting current output by the driving transistor T1 may change. The storage capacitor Cst may maintain the voltage at the gate electrode of the driving transistor T1 for one frame. The gate electrode of the driving transistor T1 may be connected to the third transistor T3 so that the data voltage DATA applied to the first electrode of the driving transistor T1 may pass through the third transistor T3 and may be transmitted to the gate electrode of the driving transistor T1. The gate electrode of the driving transistor T1 may be connected to the fourth transistor T4, may receive the first initialization voltage Vinit, and may be initialized.

The second transistor T2 is a p-type (kind) transistor, and may have the silicon semiconductor as a semiconductor layer. The second transistor T2 may allow the data voltage DATA to be received into the pixel. A gate electrode of the second transistor T2 may be connected to the first scan line SL1 and one electrode (or a lower boost electrode) of the boost capacitor C_{boost}. The first electrode of the second transistor T2 may be connected to the data line DL. A second electrode of the second transistor T2 may be connected to the first electrode of the driving transistor T1. When the second transistor T2 is turned on by the voltage with negative polarity from among the first scan signal GW transmitted through the first scan line SL1, the data voltage DATA transmitted through the data line DL may be transmitted to the first electrode of the driving transistor T1, and the data voltage DATA may be finally transmitted to the gate electrode of the driving transistor T1 and may be stored in the storage capacitor Cst.

The third transistor T3 may be an n-type (kind) transistor and may have an oxide semiconductor as the semiconductor layer. The third transistor T3 may electrically connect the second electrode of the driving transistor T1 and the gate electrode of the driving transistor T1. As a result, the third transistor T3 compensates the data voltage DATA by a threshold voltage of the driving transistor T1 and stores the same in the second storage electrode of the storage capacitor Cst. A gate electrode of the third transistor T3 may be connected to the second scan line SL2, and a first electrode of the third transistor T3 may be connected to the second electrode of the driving transistor T1. A second electrode of the third transistor T3 may be connected to the second storage electrode of the storage capacitor Cst, the gate electrode of the driving transistor T1, and another electrode (hereinafter referred to as an upper boost electrode) of the boost capacitor C_{boost}. The third transistor T3 may be turned on by the voltage with positive polarity from among the second scan signal GC received through the second scan line SL2, may connect the gate electrode of the driving transistor T1 and the second electrode of the driving transistor T1, may be configured to transmit the voltage applied to the gate electrode of the driving transistor T1 to the second storage electrode of the storage capacitor Cst, and may store the same in the storage capacitor Cst. The voltage may be stored in the storage capacitor Cst by storing the voltage at the gate electrode of the driving transistor T1 if (e.g., when) the driving transistor T1 is turned off and compensating a threshold voltage Vth value of the driving transistor T1.

The fourth transistor T4 may be an n-type (kind) transistor, and may have an oxide semiconductor as the semiconductor layer. The fourth transistor T4 may initialize the gate electrode of the driving transistor T1 and the second storage electrode of the storage capacitor Cst. A gate electrode of the fourth transistor T4 may be connected to the initialization control line GL, and the first electrode of the fourth transistor T4 may be connected to the first initialization voltage line VIL1. The second electrode of the fourth transistor T4 may be connected to the second electrode of the third transistor T3, the second storage electrode of the storage capacitor Cst, the gate electrode of the driving transistor T1, and the upper boost electrode of the boost capacitor C_{boost}. The fourth transistor T4 may be turned on by the voltage with positive polarity from among the initialization control signal GI received through the initialization control line GL, and may be configured to transmit the first initialization voltage Vinit to the gate electrode of the driving transistor T1, the second storage electrode of the storage capacitor Cst, and the upper boost electrode of the boost capacitor C_{boost} to initialize the same.

The fifth transistor T5 and the sixth transistor T6 are p-type (kind) transistors, and have silicon semiconductors as the semiconductor layers.

The fifth transistor T5 may be configured to transmit the driving voltage ELVDD to the driving transistor T1. A gate electrode of the fifth transistor T5 may be connected to the light emitting control line EML, a first electrode of the fifth transistor T5 may be connected to the driving voltage line VL, and a second electrode of the fifth transistor T5 may be connected to the first electrode of the driving transistor T1.

The sixth transistor T6 may be configured to transmit the light emitting current output by the driving transistor T1 to the light emitting device ED. A gate electrode of the sixth transistor T6 may be connected to the light emission control line EML, a first electrode of the sixth transistor T6 may be connected to the second electrode of the driving transistor T1, and a second electrode of the sixth transistor T6 may be connected to the anode of the light emitting device ED.

The seventh transistor T7 may be an n-type (kind) transistor, and may have the same oxide semiconductor as the semiconductor layer. The seventh transistor T7 may initialize the anode of the light emitting device ED. The seventh transistor T7 may also be referred to as an anode initializing transistor. A gate electrode of the seventh transistor T7 may be connected to the bypass control line BL, a first electrode of the seventh transistor T7 may be connected to the anode of the light emitting device ED, and a second electrode of the seventh transistor T7 may be connected to the second initialization voltage line VIL2. When the seventh transistor T7 is turned on by the voltage with positive polarity from among the bypass control signal GB flowing through the bypass control line BL, the second initialization voltage AVinit may be applied to the anode of the light emitting device ED to be initialized.

One pixel PX has been described as including seven transistors T1 to T7 and two capacitors (the storage capacitor Cst and the boost capacitor C_{boost}), and the boost capacitor C_{boost} may not be provided depending on embodiments. The third transistor T3, the fourth transistor T4, and the seventh transistor T7 may include (e.g., are made of) n-type (kind) transistors in the above-noted embodiments, and one of them may include (e.g., may be made of) an n-type (kind) transistor or the other thereof may include (e.g., may be made of) an n-type (kind) transistor.

A thin-film transistor included in the display device according to one or more embodiments will now be described in more detail with reference to FIG. 4 to FIG. 6.

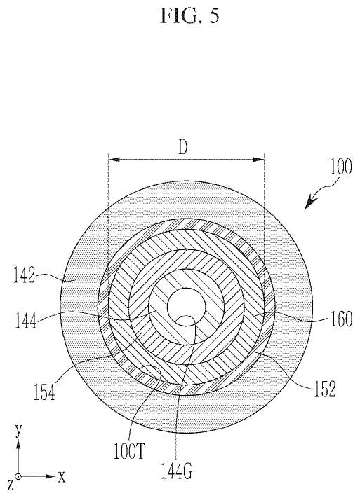

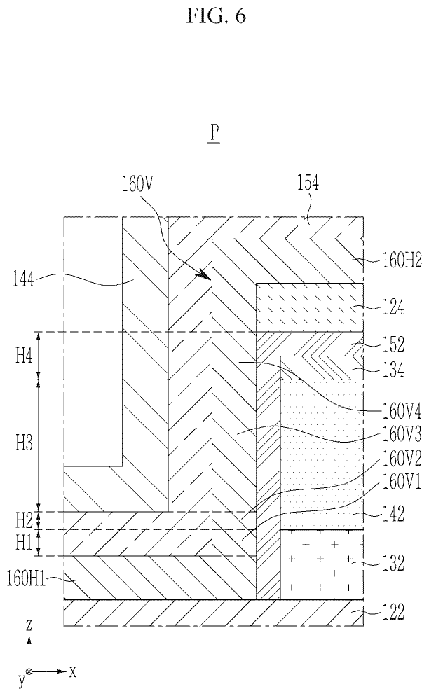

FIG. 4 shows a cross-sectional view of a thin-film transistor according to one or more embodiments. FIG. 5 shows a top plan view of a region corresponding to a line A-A′ of FIG. 4. FIG. 6 shows a partially enlarged view of a region P of FIG. 4.

Referring to FIG. 4 to FIG. 6, the thin-film transistor 100 may include a substrate 110, a first electrode 122 arranged on the substrate 110, a first gate electrode 142 arranged on the first electrode 122, a first buffer layer 132 arranged between the first electrode 122 and the first gate electrode 142, a first gate insulating layer 152 arranged on the first gate electrode 142, a second buffer layer 134 arranged between the first gate electrode 142 and the first gate insulating layer 152, a second electrode 124 arranged on the first gate insulating layer 152, an active layer 160 connected to the first electrode 122 and the second electrode 124, a second gate electrode 144 arranged on the active layer 160, and a second gate insulating layer 154 arranged between the active layer 160 and the second gate electrode 144.

The thin-film transistor 100 may be arranged on the substrate 110 of the above-described display device 10. However, without being limited thereto, the thin-film transistor 100 may be arranged on another substrate in addition to the substrate 110 of the display device 10. Hereinafter, the thin-film transistor 100 will be assumed to be arranged on the substrate 110 of the display device 10.

The substrate 110 may be a transparent insulating substrate. For example, the substrate 110 may include a glass substrate, a quartz substrate, and transparent resin. The substrate 110 may include a polymer with high heat resistance. For example, the substrate 110 may include one of polyether sulphone, polyacrylate, polyetherimide, polyethyelene naphthalate, polyethyelene terepthalate, polyphenylene sulfide, polyarylate, polyimide, polycarbonate, cellulose triacetate, cellulose acetate propionate, polyarylene ether sulfone, and/or one or more (e.g., any suitable) combinations thereof. However, this is an example, and the material included by the substrate 110 may be changeable in many ways.

The first electrode 122 may be arranged on the substrate 110. The width of the first electrode 122 may be less than the width of the substrate 110. For example, the first electrode 122 may be arranged on a portion of the substrate 110.

The first buffer layer 132, the first gate electrode 142, the second buffer layer 134, the first gate insulating layer 152, and the second electrode 124 may be sequentially arranged on the first electrode 122.

The thin-film transistor 100 may include the first buffer layer 132, the first gate electrode 142, the second buffer layer 134, and the first gate insulating layer 152 sequentially stacked on the first electrode 122, and an opening 100T penetrating the second electrode 124 and extending in a third direction Z that is normal (e.g., perpendicular) to the substrate 110.

The opening 100T may be defined by the first electrode 122, the first gate insulating layer 152, and the second electrode 124. For example, an upper surface of the first electrode 122 overlapping the opening 100T may configure a bottom surface of the opening 100T, and a lateral surface of the first gate insulating layer 152 and a lateral surface of the second electrode 124 may be arranged on substantially the same boundary and may configure an internal wall of the opening 100T.

The opening 100T may have a circular shape, an oval shape, or a polygonal shape in a plan view. Elements being extended along a circumference of an external wall of the opening 100T and elements being extended along an internal wall of the opening 100T may have the same (e.g., substantially the same) shape as the opening 100T in a plan view. For example, as shown in FIG. 5, the opening 100T may have a circular shape in a plan view.

As shown in FIG. 5, the first gate electrode 142 being extended along the circumference of the external wall of the opening 100T, the first gate insulating layer 152 configuring the internal wall of the opening 100T, the active layer 160, the second gate insulating layer 154, and the second gate electrode 144 sequentially arranged on the internal wall of the opening 100T may have the same (e.g., substantially the same) circular shape as the opening 100T in a plan view. However, this is an example, and the opening 100T may have one or more suitable shapes, and hence, the elements being extended along the circumference of the external wall of the opening 100T and the elements being extended along the internal wall of the opening 100T may have one or more suitable shapes in a plan view.

The width D of the opening 100T may be less than the width of the first electrode 122. For example, the opening 100T may overlap a portion of the first electrode 122 in the third direction Z that is normal (e.g., perpendicular) to the substrate 110.

In one or more embodiments, the width D of the opening 100T may be in a range of about 1.5 μm to about 3 μm. The width D of the opening 100T may represent the width between the first gate insulating layer 152 configuring the internal wall of the opening 100T or the width between the first gate electrode 142 configuring the internal wall of the opening 100T.

When the width D of the opening 100T has the above numerical range, the size of the thin-film transistor 100 may be minimized or reduced to increase the number of thin-film transistors 100 included in the high-resolution display device, and modify the arrangement of the thin-film transistors 100 in the high-resolution display device in many ways. However, the numerical range of the width D of the opening 100T is an example, and the numerical range of the width D of the opening 100T may be changeable in many ways.

The first buffer layer 132 may cover a portion of the upper surface and a lateral surface of the first electrode 122 and the upper surface of the substrate 110 not overlapping the first electrode 122, and may be around (e.g., surround) the opening 100T. For example, the first buffer layer 132 may overlap a portion of the first electrode 122 in the third direction Z that is the normal (e.g., perpendicular) direction.

The first gate electrode 142 may be arranged on the first buffer layer 132, and may be around (e.g., surround) the opening 100T. The first gate electrode 142 may overlap a portion of the first electrode 122 in the third direction Z that is the normal (e.g., perpendicular) direction.

The width of the first gate electrode 142 in the first direction X may be less than the width of the first buffer layer 132 in the first direction X. One lateral surface of the first gate electrode 142 and one lateral surface of the first buffer layer 132 may be arranged on substantially the same boundary, and another lateral surface thereof may be arranged between both sides (e.g., opposite sides) of the first buffer layer 132. For example, one lateral surface of the first gate electrode 142 may overlap a corresponding lateral surface of the first buffer layer 132 in the third direction Z.

Hence, the first gate electrode 142 may be arranged on a portion of the upper surface of the first buffer layer 132, and steps may occur between the first gate electrode 142 and the first buffer layer 132. For example, the first gate electrode 142 may overlap a portion of the first buffer layer 132 in the third direction Z.

The second buffer layer 134 may cover the first gate electrode 142 and may be around (e.g., surround) the opening 100T. The second buffer layer 134 may overlap a portion of the first electrode 122 in the third direction Z that is the normal (e.g., perpendicular) direction.

The second buffer layer 134 may cover the upper surface of the first buffer layer 132 not overlapping the first gate electrode 142. One lateral surface of the second buffer layer 134 and one lateral surface of the first gate electrode 142 may be arranged on the same (e.g., substantially the same) boundary. The second buffer layer 134 may be conformally extended along the surface of the first gate electrode 142 and the surface of the first buffer layer 132. For example, a lateral surface of the second buffer layer 134 may be extended along a lateral surface of the first gate electrode 142 in the third direction Z.

The first buffer layer 132 and the second buffer layer 134 may not be provided depending on embodiments.

The first gate insulating layer 152 may be conformally extended along the surface shape of the second buffer layer 134 to cover the second buffer layer 134, and may be around (e.g., surround) the opening 100T. The first gate insulating layer 152 may overlap a portion of the first electrode 122 in the third direction Z that is the normal (e.g., perpendicular) direction.

The first gate insulating layer 152 may be conformally extended in the third direction Z that is the normal (e.g., perpendicular) direction along a lateral surface of the second buffer layer 134, a lateral surface of the first gate electrode 142, and a lateral surface of the first buffer layer 132 arranged on the same (e.g., substantially the same) boundary on the first electrode 122, and may configure the internal wall of the opening 100T. An end of the first gate insulating layer 152 configuring the internal wall of the opening 100T may contact the upper surface of the first electrode 122.

The second electrode 124 may cover the upper surface of the first gate insulating layer 152, and may be around (e.g., surround) the opening 100T. One lateral surface of the second electrode 124 may be arranged on the same (e.g., substantially the same) boundary as the lateral surface of the first gate insulating layer 152 configuring a portion of the internal wall of the opening 100T and may configure the rest of the internal wall of the opening 100T.

The first electrode 122, the first gate electrode 142, and the second electrode 124 may include metals such as molybdenum (Mo), aluminum (AI), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), or copper (Cu), and/or one or more (e.g., any suitable) combinations thereof, and may be a single layer or a multilayer. For example, the first electrode 122 and the second electrode 124 may include (e.g., may be made of) a multilayer structure of Ti/Al/Ti. However, one or more embodiments is not limited thereto, and the material included by the first electrode 122, the first gate electrode 142, and the second electrode 124 may be changeable in many ways.

The first buffer layer 132 and the second buffer layer 134 may each include a silicon compound. For example, the first buffer layer 132 and the second buffer layer 134 may each include silicon oxide, silicon nitride, silicon oxynitride, silicon carbonitride, silicon oxycarbide, hafnium oxide, yttrium oxide, and/or one or more (e.g., any suitable) combinations thereof, and may be a single layer or a multilayer. However, the material included by the first buffer layer 132 and the second buffer layer 134 is not limited thereto, and may be changeable in many ways. For example, if (e.g., when) each of the first buffer layer 132 and the second buffer layer 134 is made into a double layer, one layer may include silicon nitride, and the other layer may include silicon oxide.

The first buffer layer 132 and the second buffer layer 134 may prevent or reduce impurities degrading the characteristic of the semiconductor from being diffused and prevent or reduce moisture from permeating.

The first gate insulating layer 152 may include a silicon compound. For example, the first gate insulating layer 152 may include silicon oxide, silicon nitride, and/or one or more (e.g., any suitable) combinations thereof. However, this is an example, and the material included by the first gate insulating layer 152 may be changeable in many ways. For example, the first gate insulating layer 152 may include the same material as the first buffer layer 132 and the second buffer layer 134.

The active layer 160 may be conformally extended along the bottom surface and the internal wall of the opening 100T and the upper surface of the second electrode 124, and may contact the first electrode 122 and the second electrode 124. For example, the active layer 160 may be extended along the upper surface of the first electrode 122 forming the bottom surface of the opening 100T, the lateral surface of the first gate insulating layer 152 and the lateral surface of the second electrode 124 configuring the internal wall of the opening 100T, and the upper surface of the second electrode 124 around (e.g., surrounding) the opening 100T.

For example, the active layer 160 may include a first horizontal portion 160H1 being extended in the first direction X that is a horizontal direction along the upper surface of the first electrode 122 configuring the bottom surface of the opening 100T, a normal (e.g., perpendicular) portion 160V being extended in the third direction Z that is the normal (e.g., perpendicular) direction along the lateral surface of the first gate insulating layer 152 and the lateral surface of the second electrode 124 configuring the internal wall of the opening 100T from the first horizontal portion 160H1, and a second horizontal portion 160H2 being extended in the first direction X that is the horizontal direction along the upper surface or a portion of the upper surface of the second electrode 124 around (e.g., surrounding) the opening 100T from the normal (e.g., perpendicular) portion 160V.

The first horizontal portion 160H1 of the active layer 160 may cover a portion of the upper surface of the first electrode 122 overlapping the opening 100T. The normal (e.g., perpendicular) portion 160V of the active layer 160 may cover the lateral surface of the first gate insulating layer 152 and the lateral surface of the second electrode 124 defining the internal wall of the opening 100T. The second horizontal portion 160H2 of the active layer 160 may cover a portion of the upper surface of the second electrode 124 around (e.g., surrounding) the opening 100T.

The first horizontal portion 160H1, the normal (e.g., perpendicular) portion 160V, and the second horizontal portion 160H2 of the active layer 160 may be integrally formed, and may have the same (e.g., substantially the same) thickness. The thickness of the first horizontal portion 160H1 and the second horizontal portion 160H2 may represent the thickness in the third direction Z, and the thickness of the normal (e.g., perpendicular) portion 160V may represent the thickness in the first direction X.

One of the first electrode 122 contacting the first horizontal portion 160H1 of the active layer 160 and the second electrode 124 contacting a portion of the normal (e.g., perpendicular) portion 160V of the active layer 160 and the second horizontal portion 160H2 may be a source electrode, and the other thereof may be a drain electrode. For example, the first electrode 122 may be the source electrode, and the second electrode 124 may be the drain electrode. The first horizontal portion 160H1 of the active layer 160 may be a source region, a portion of the normal (e.g., perpendicular) portion 160V of the active layer 160 and the second horizontal portion 160H2 may be a drain region, and the remaining portion of the normal (e.g., perpendicular) portion 160V of the active layer 160 may be a channel region.

For another example, the first electrode 122 may be the drain electrode, and the second electrode 124 may be the source electrode. The first horizontal portion 160H1 of the active layer 160 may be the drain region, a portion of the normal (e.g., perpendicular) portion 160V of the active layer 160 and the second horizontal portion 160H2 may be the source region, and the remaining portion of the normal (e.g., perpendicular) portion 160V of the active layer 160 may be the channel region.

As described previously, the normal (e.g., perpendicular) portion 160V that corresponds to the channel region of the active layer 160 may be extended in the third direction Z that is normal (e.g., perpendicular) to the substrate 110. Hence, the length of the channel of the active layer 160 may be defined by the normal (e.g., perpendicular) portion 160V of the active layer 160 being extended in the third direction Z that is normal (e.g., perpendicular) to the substrate 110, and the width of the channel may be defined by the circumference of the normal (e.g., perpendicular) portion 160V of the active layer 160 around (e.g., surrounding) the internal wall of the opening 100T.

In one or more embodiments, the same voltage may be applied to the first gate electrode 142 and the second gate electrode 144. For example, as the same voltage is applied to the first gate electrode 142 and the second gate electrode 144 and carrier mobility or carrier concentration of the channel region of the active layer 160 arranged between the first gate electrode 142 and the second gate electrode 144 increases, the switch characteristic of the thin-film transistor may be improved. However, one or more embodiments is not limited thereto, and may be modifiable in many ways. For example, as different voltages are applied to the first electrode 122 and the second electrode 124 to control the carrier mobility or carrier concentration of the channel region of the active layer 160 arranged between the first gate electrode 142 and the second gate electrode 144, adjustability of the threshold voltage may be improved.

The active layer 160 may include an oxide semiconductor material. The oxide semiconductor material may include at least one of zinc (Zn), indium (In), gallium (Ga), or tin (Sn). In one or more embodiments, the oxide semiconductor material may include metals such as zinc (Zn), indium (In), gallium (Ga), or tin (Sn), and/or one or more (e.g., any suitable) combinations of oxides thereof. For example, the oxide semiconductor material may include at least one of zinc oxide (ZnO), zinc-tin oxide (ZTO), zinc-indium oxide (ZIO), indium oxide (InO), titanium oxide (TiO), indium-gallium-zinc oxide (IGZO), or indium-zinc-tin oxide (IZTO). However, this is an example, and the material included by the active layer 160 may be modifiable in many ways.

The second gate insulating layer 154 may be arranged on the active layer 160 and the second electrode 124. The second gate insulating layer 154 may be conformally extended along the surface of the active layer 160 and the surface of the second electrode 124. Hence, a portion of the second gate insulating layer 154 may be arranged on the internal wall and the bottom surface of the opening 100T, and the remaining portion thereof may be arranged on the upper surface of the second electrode 124.

The second gate insulating layer 154 may include the same material as the first gate insulating layer 152. However, without being limited thereto, the second gate insulating layer 154 may include an insulating material that is different from the first gate insulating layer 152.

The second gate electrode 144 may be arranged on the second gate insulating layer 154. As the width of the second gate electrode 144 in the first direction X is less than the width of the second gate insulating layer 154 in the first direction X, the second gate electrode 144 may be arranged on a portion of the second gate insulating layer 154.

The second gate electrode 144 may be conformally extended along the surface of the second gate insulating layer 154. As described above, as the second gate insulating layer 154 is extended along the surface of the active layer 160, the second gate electrode 144 may be extended along the surface shape of the active layer 160 with the second gate insulating layer 154 therebetween.

As the second gate electrode 144 is conformally extended along the surface of the second gate insulating layer 154, a portion of the second gate electrode 144 may be arranged on the internal wall and the bottom surface of the opening 100T, and the remaining portion may be arranged on the upper surface of the second gate insulating layer 154.

The second gate electrode 144 may fill a set or predetermined region of the opening 100T, and may define a gap region 144G in the opening 100T. The gap region 144G of the second gate electrode 144 may be defined by the lateral surface of the second gate electrode 144 arranged on the internal wall of the opening 100T and the upper surface of the second gate electrode 144 arranged on the bottom surface of the opening 100T.

As the second gate electrode 144 is arranged to extend along the internal wall of the opening 100T with the second gate insulating layer 154 and the active layer 160 therebetween, defining the gap region 144G, the gap region 144G in a plan view may have the same (e.g., substantially the same) shape as the opening 100T. For example, as shown in FIG. 5, the shape of the gap region 144G of the second gate electrode 144 in a plan view may have the same (e.g., substantially the same) circular shape as the opening 100T in a plan view.

As the second gate electrode 144 is extended in the third direction Z that is normal (e.g., perpendicular) to the substrate 110 on the internal wall of the opening 100T, the normal (e.g., perpendicular) portion 160V of the active layer 160 being extended in the third direction Z along the internal wall of the opening 100T may be arranged between the first gate electrode 142 and the second gate electrode 144. For example, as the first gate electrode 142 is arranged on a first side of the normal (e.g., perpendicular) portion 160V of the active layer 160, and the second gate electrode 144 is arranged on a second side thereof, the normal (e.g., perpendicular) portion 160V of the active layer 160 may overlap the first gate electrode 142 and the second gate electrode 144 in the first direction X that is parallel to the substrate 110.

The second gate electrode 144 may include the same metal material as the first gate electrode 142. However, without being limited thereto, the second gate electrode 144 may have a metal material that is different from the first gate electrode 142.

In one or more embodiments, as shown in FIG. 6, the normal (e.g., perpendicular) portion 160V of the active layer 160 may include a first normal (e.g., perpendicular) portion 160V1, a second normal (e.g., perpendicular) portion 160V2, a third normal (e.g., perpendicular) portion 160V3, and a fourth normal (e.g., perpendicular) portion 160V4 continuously arranged on the first horizontal portion 160H1 in the normal (e.g., perpendicular) third direction Z. The first normal (e.g., perpendicular) portion 160V1, the second normal (e.g., perpendicular) portion 160V2, the third normal (e.g., perpendicular) portion 160V3, and the fourth normal (e.g., perpendicular) portion 160V4 of the active layer 160 may be the channel region of the active layer 160.

In more detail, the first normal (e.g., perpendicular) portion 160V1 of the active layer 160 may overlap the first buffer layer 132 on a first side in the first direction X that is parallel to the substrate 110, and may overlap the second gate insulating layer 154 on a second side (e.g., an opposite side) thereof. For example, the first normal (e.g., perpendicular) portion 160V1 of the active layer 160 may not overlap the first gate electrode 142 and the second gate electrode 144 in the first direction X.

The second normal (e.g., perpendicular) portion 160V2 of the active layer 160 may overlap the first gate electrode 142 on a first side in the first direction X, and may overlap the second gate insulating layer 154 on a second side (e.g., an opposite side) thereof. For example, the second normal (e.g., perpendicular) portion 160V2 of the active layer 160 may overlap the first gate electrode 142 and may not overlap the second gate electrode 144 in the first direction X.

The third normal (e.g., perpendicular) portion 160V3 of the active layer 160 may overlap the first gate electrode 142 on a first side in the first direction X and may overlap the second gate electrode 144 on a second side (e.g., opposite side) thereof.

The fourth normal (e.g., perpendicular) portion 160V4 of the active layer 160 may overlap the second buffer layer 134 and the first gate insulating layer 152 arranged between the first gate electrode 142 and the second electrode 124 on a first side in the first direction X, and may overlap the second gate electrode 144 on a second side (e.g., opposite side) thereof. For example, the fourth normal (e.g., perpendicular) portion 160V4 of the active layer 160 may not overlap the first gate electrode 142 and may overlap the second gate electrode 144 in the first direction X.

The third normal (e.g., perpendicular) portion 160V3 overlapping the first gate electrode 142 and the second gate electrode 144 in the first direction X from among the first to fourth normal (e.g., perpendicular) portions 160V1, 160V2, 160V3, and 160V4 configuring the channel region of the active layer 160 may have higher carrier mobility or carrier concentration than the first normal (e.g., perpendicular) portion 160V1 not overlapping the first gate electrode 142 and the second gate electrode 144 in the first direction X and the second normal (e.g., perpendicular) portion 160V2 and the fourth normal (e.g., perpendicular) portion 160V4 each overlapping a respective one selected from among the first gate electrode 142 and the second gate electrode 144. For example, the third normal (e.g., perpendicular) portion 160V3, which overlaps both the first gate electrode 142 and the second gate electrode 144 in the first direction X, may have higher carrier mobility or carrier concentration than the first normal (e.g., perpendicular) portion 160V1, which does not overlap either the first gate electrode 142 or the second gate electrode 144 in the first direction X. Additionally, the second normal (e.g., perpendicular) portion 160V2 and the fourth normal (e.g., perpendicular) portion 160V4, which each overlap a respective one of the first gate electrode 142 or the second gate electrode 144, may also have lower carrier mobility or carrier concentration compared to the third normal (e.g., perpendicular) portion 160V3.

The first normal (e.g., perpendicular) portion 160V1 of the active layer 160 may have a first thickness H1 in the third direction Z that is normal (e.g., perpendicular) to the substrate 110, the second normal (e.g., perpendicular) portion 160V2 may have a second thickness H2, the third normal (e.g., perpendicular) portion 160V3 may have a third thickness H3, and the fourth normal (e.g., perpendicular) portion 160V4 may have a fourth thickness H4.

In one or more embodiments, the first thickness H1, the second thickness H2, the third thickness H3, and the fourth thickness H4 may be different from each other. For example, the first thickness H1 may be greater than the second thickness H2 and may be less than the third thickness H3 and the fourth thickness H4. The second thickness H2 may be less than the first thickness H1, the third thickness H3, and the fourth thickness H4. The third thickness H3 may be greater than the first thickness H1, the second thickness H2, and the fourth thickness H4, and the third thickness H3 may be greater than the sum of the first thickness H1, the second thickness H2, and the fourth thickness H4. The fourth thickness H4 may be less than the third thickness H3, and may be greater than the first thickness H1 and the second thickness H2. For example, the third thickness H3 may be the greatest and the second thickness H2 may be the least.

As described above, if (e.g., when) the third thickness H3 is the greatest from among the first to fourth thicknesses H1, H2, H3, and H4, the area or the thickness of the channel region formed with the third normal (e.g., perpendicular) portion 160V3 with the highest carrier mobility or carrier concentration becomes the greatest from among the first to fourth normal (e.g., perpendicular) portions 160V1, 160V2, 160V3, and 160V4 configuring the channel region of the active layer 160 so the carrier mobility or carrier concentration of the normal (e.g., perpendicular) portion 160V of the active layer 160 configuring the channel region may be improved, and the switch characteristic of the thin-film transistor 100 may be improved. However, this is an example, and the first to fourth thicknesses H1, H2, H3, and H4 of the first to fourth normal (e.g., perpendicular) portions 160V1, 160V2, 160V3, and 160V4 of the active layer 160 and their relationships may be modifiable in many ways.

According to the thin-film transistor 100, as the first gate electrode 142 and the second gate electrode 144 are arranged on respective sides of the active layer 160 including the channel region being extended in the normal (e.g., perpendicular) direction, the carrier mobility, adjustability of the threshold voltage, and the switching rates may be improved, and the thin-film transistor with improved efficiency of power consumption may be provided.

For example, according to the thin-film transistor 100, as the first gate electrode 142 and the second gate electrode 144 are arranged on respective sides of the active layer 160, which includes the channel region extending in the normal (e.g., perpendicular) direction, several performance improvements may be achieved. The arrangement of the gate electrodes on either side of the channel region allows for enhanced control of the electric field, leading to improved carrier mobility and higher switching rates. This configuration also facilitates better adjustability of the threshold voltage, which is crucial for optimizing the transistor's performance in various applications.

Furthermore, the specific design of the active layer 160, with its distinct normal (e.g., perpendicular) portions 160V1, 160V2, 160V3, and 160V4, contributes to the overall efficiency of the device. The third normal (e.g., perpendicular) portion 160V3, which overlaps both the first gate electrode 142 and the second gate electrode 144, exhibits higher carrier mobility or carrier concentration compared to the other portions. This results in a more efficient channel region, enhancing the transistor's switching characteristics.

The varying thicknesses of the normal (e.g., perpendicular) portions also play a significant role in the device's performance. The third thickness H3, being the greatest among the first to fourth thicknesses H1, H2, H3, and H4, ensures that the area or thickness of the channel region with the highest carrier mobility or carrier concentration is maximized. This design choice further improves the carrier mobility and the overall efficiency of the thin-film transistor 100.

In summary, the innovative design of the thin-film transistor 100, with its strategically arranged gate electrodes and enhanced active layer structure, leads to significant improvements in carrier mobility, threshold voltage adjustability, and switching rates. These enhancements contribute to a thin-film transistor with improved efficiency of power consumption, making it highly suitable for advanced display devices and other high-performance applications.

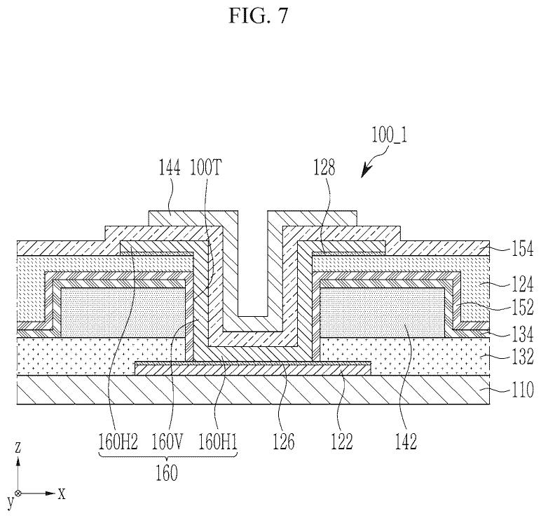

A display device according to one or more suitable embodiments will now be described in more detail with reference to FIG. 7 to FIG. 10. In one or more embodiments given, the same reference numerals are used for the same configuration as the previously described embodiments, and duplicate explanations may not be provided or may be simplified, with the differences being mainly described.

FIG. 7 to FIG. 10 show cross-sectional views of thin-film transistors according to several embodiments.

The thin-film transistor 100_1 may further include a first transparent electrode 126 arranged between the first electrode 122 and the active layer 160 and a second transparent electrode 128 arranged between the second electrode 124 and the active layer 160.

For example, the first transparent electrode 126 may be arranged between the first electrode 122 and the first horizontal portion 160H1 of the active layer 160. The first transparent electrode 126 may configure the bottom surface of the opening 100T.

The width of the first transparent electrode 126 in the first direction X may be equal (e.g., substantially equal) to the width of the first electrode 122 in the first direction X. Both ends of the first transparent electrode 126 and both (e.g., simultaneously) ends of the first electrode 122 may be arranged on the same (e.g., substantially the same) boundary. For example, the first transparent electrode 126 may cover the upper surface of the first electrode 122. For example, an end of the first transparent electrode 126 may overlap a corresponding end of the first electrode 122 in the third direction Z. However, without being limited thereto, the first transparent electrode 126 may cover a portion of the upper surface of the first electrode 122.

The second transparent electrode 128 may be arranged between the second electrode 124 and the second horizontal portion 160H2 of the active layer 160. The width of the second transparent electrode 128 in the first direction X may be less than the width of the second electrode 124 in the first direction X. The second transparent electrode 128 may cover a portion of the upper surface of the second electrode 124. The lateral surface of the second transparent electrode 128 and the lateral surface of the second electrode 124 configuring the internal wall of the opening 100T may be arranged on the same (e.g., substantially the same) boundary, and may configure the internal wall of the opening 100T. For example, an end of the second transparent electrode 128 may overlap a corresponding end of the second electrode 124 in a third direction Z. However, without being limited thereto, the second transparent electrode 128 may cover the upper surface of the second electrode 124.

The first transparent electrode 126 and the second transparent electrode 128 may both (e.g., simultaneously) include a transparent conductive oxide. For example, the transparent conductive oxide may include indium tin oxide (ITO), indium zinc oxide (IZO), zinc oxide (ZnO), tin oxide (SnO), titanium oxide (TiO), aluminum-doped zinc oxide (AZO), gallium-doped zinc oxide (GZO), fluorine-doped tin oxide (FTO), antimony-doped tin oxide (ATO), and/or one or more (e.g., any suitable) combinations thereof. However, the material included by each of the first transparent electrode 126 and the second transparent electrode 128 is not limited thereto, and may be modifiable in many ways.

The thin-film transistor 100_1 according to the present embodiment may have the same (e.g., substantially the same) effect as the thin-film transistor 100 according to one or more embodiments. As the thin-film transistor 100_1 includes the first transparent electrode 126 and the second transparent electrode 128 arranged between the first electrode 122 and the active layer 160 and between the second electrode 124 and the active layer 160 respectively, the electrical characteristic between the first electrode 122 and the first horizontal portion 160H1 of the active layer 160 and between the second electrode 124 and the second horizontal portion 160H2 of the active layer 160 may be improved.

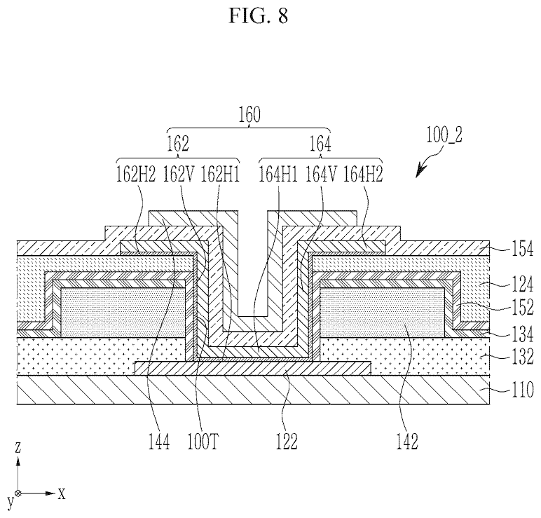

A thin-film transistor 100_2 according to one or more embodiments shown in FIG. 8, may have the active layer 160 including a plurality of layers, differing from the thin-film transistor 100 shown in FIG. 4.

The active layer 160 of the thin-film transistor 100_2 may include a first active layer 162 conformally being extended along the bottom surface and the internal wall of the opening 100T and the upper surface of the second electrode 124, and contacting the first electrode 122 and the second electrode 124, and a second active layer 164 conformally being extended along the surface of the first active layer 162.

For example, the first active layer 162 may include a first horizontal portion 162H1 being extended in the first direction X that is the horizontal direction along the upper surface of the first electrode 122 configuring the bottom surface of the opening 100T, a normal (e.g., perpendicular) portion 162V being extended in the third direction Z that is the normal (e.g., perpendicular) direction along the lateral surface of the first gate insulating layer 152 and the lateral surface of the second electrode 124 configuring the internal wall of the opening 100T from the first horizontal portion 162H1, and a second horizontal portion 162H2 being extended in the first direction X that is the horizontal direction along the upper surface of the second electrode 124 around (e.g., surrounding) the opening 100T from the normal (e.g., perpendicular) portion 162V.

The second active layer 164 may be conformally extended along the surface shape of the first active layer 162, and may cover the first active layer 162. For example, the first active layer 162 may be arranged between the internal wall of the opening 100T and the second active layer 164, between the bottom surface of the opening 100T and the second active layer 164, and between the second electrode 124 and the second active layer 164.

Being extended along the surface shape of the first active layer 162, the second active layer 164 may have the same (e.g., substantially the same) arrangement as the first active layer 162. For example, the second active layer 164 may include a first horizontal portion 164H1 arranged on the first horizontal portion 162H1 of the first active layer 162 and being extended in the first direction X, a normal (e.g., perpendicular) portion 164V arranged on the normal (e.g., perpendicular) portion 162V of the first active layer 162 and being extended in the third direction Z, and a second horizontal portion 164H2 arranged on the second horizontal portion 162H2 of the first active layer 162 and being extended in the first direction X.

The first horizontal portion 164H1 of the second active layer 164 may overlap the upper surface of the first electrode 122 configuring the bottom surface of the opening 100T in the third direction Z.

The normal (e.g., perpendicular) portion 164V of the second active layer 164 may overlap the first gate insulating layer 152 and the second electrode 124 configuring the internal wall of the opening 100T in the first direction X.

The second horizontal portion 164H2 of the second active layer 164 may overlap a portion of the second electrode 124 around (e.g., surrounding) the opening 100T in the third direction Z. An end of the second horizontal portion 162H2 of the first active layer 162 and an end of the second horizontal portion 164H2 of the second active layer 164 may be arranged on the same (e.g., substantially the same) boundary. For example, an end of the second horizontal portion 164H2 of the second active layer 164 may overlap a corresponding end of the second horizontal portion 162H2 of the first active layer 162 in a third direction Z. However, the present embodiment is not limited thereto, and may be modifiable in many ways. For example, the end of the second horizontal portion 162H2 of the first active layer 162 is arranged to protrude further in the first direction X than the end of the second horizontal portion 164H2 of the second active layer 164, and the second horizontal portion 164H2 of the second active layer 164 may cover a portion of the second horizontal portion 162H2 of the first active layer 162.

For another example, as the end of the second horizontal portion 164H2 of the second active layer 164 is arranged to protrude further in the first direction X than the end of the second horizontal portion 162H2 of the first active layer 162, the second horizontal portion 164H2 of the second active layer 164 may cover the upper surface and the lateral surface of the second horizontal portion 162H2 of the first active layer 162, and the upper surface of the second electrode 124 on which the second horizontal portion 162H2 of the first active layer 162 is not arranged.

In one or more embodiments, the thickness of the first active layer 162 may be different from the thickness of the second active layer 164. For example, the thickness of the first active layer 162 may be less than the thickness of the second active layer 164. For example, the first horizontal portion 162H1 of the first active layer 162 may be thinner than the first horizontal portion 164H1 of the second active layer 164, the normal (e.g., perpendicular) portion 162V of the first active layer 162 may be thinner than the normal (e.g., perpendicular) portion 164V of the second active layer 164, and the second horizontal portion 162H2 of the first active layer 162 may be thinner than the second horizontal portion 164H2 of the second active layer 164.

The thicknesses of the horizontal portions 162H1, 162H2, 164H1, and 164H2 of the first active layer 162 and the second active layer 164 may represent the thicknesses in the third direction Z, and the thicknesses of the normal (e.g., perpendicular) portions 162V and 164V of the first active layer 162 and the second active layer 164 may represent the thicknesses in the first direction X. However, one or more embodiments are not limited thereto, and may be modifiable in many ways. For example, the thickness of the first active layer 162 may be equal (e.g., substantially equal) to the thickness of the second active layer 164. For another example, the first active layer 162 may be thicker than the second active layer 164.

In one or more embodiments, the active layer 160 is shown to have two layers, and the number of layers included by the active layer 160 is not limited thereto, and may be modifiable in many ways. For example, the active layer 160 may be configured with at least two layers (e.g., two or more layers).

In one or more layers, the first active layer 162 and the second active layer 164 may each include an oxide semiconductor material. The oxide semiconductor material may include at least one of zinc (Zn), indium (In), gallium (Ga), or tin (Sn). In one or more embodiments, the oxide semiconductor material may include metals such as zinc (Zn), indium (In), gallium (Ga), or tin (Sn), and/or one or more (e.g., any suitable) combinations of the oxides thereof. For example, the oxide semiconductor material may include at least one of zinc oxide (ZnO), zinc-tin oxide (ZTO), zinc-indium oxide (ZIO), indium oxide (InO), titanium oxide (TiO), indium-gallium-zinc oxide (IGZO), or indium-zinc-tin oxide (IZTO).

The material included in the first active layer 162 may have a different composition ratio from the material included in the second active layer 164. For example, a component ratio of at least one of zinc (Zn), indium (In), gallium (Ga), or tin (Sn) included in the first active layer 162 and the second active layer 164 may be different. For example, the ratio of at least one of zinc (Zn), indium (In), gallium (Ga), or tin (Sn) included in the first active layer 162 and the second active layer 164 may be different. In more detail, the component ratio of gallium (Ga) included in the first active layer 162 may be greater than the ratio of gallium (Ga) included in the second active layer 164. For example, the ratio of gallium (Ga) included in the first active layer 162 may be greater than the ratio of gallium (Ga) included in the second active layer 164. However, this is an example, and the component ratio or the ratio of the material included by the first active layer 162 and the second active layer 164, and the material included in each of the first active layer 162 and the second active layer 164 may be modifiable in many ways.

The thin-film transistor 100_2 according to the present embodiment may have the same (e.g., substantially the same) effect as the thin-film transistor 100 according to one or more embodiments. Regarding the thin-film transistor 100_2, as the active layer 160 is formed of a plurality of layers, and the composition ratios of the material included in the layers are different, the carrier mobility or carrier concentration of the channel region of the active layer 160 may increase and the switch characteristic of the thin-film transistor 100_2 may be improved.

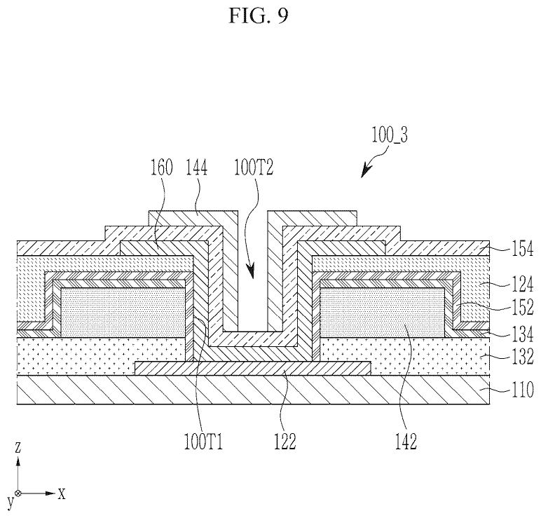

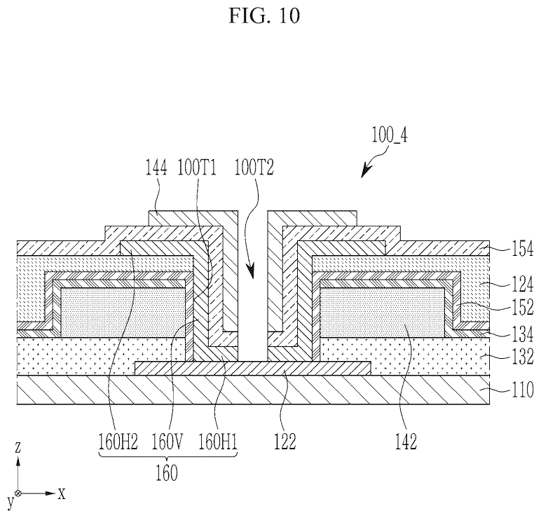

Differing from the thin-film transistor 100 according to one or more embodiments, the thin-film transistors 100_3 and 100_4 shown in FIG. 9 and FIG. 10 include a first opening 100T1 penetrating the first buffer layer 132, the first gate electrode 142, the second buffer layer 134, the first gate insulating layer 152, and the second electrode 124 sequentially stacked on the first electrode 122 and being extended in the third direction Z that is normal (e.g., perpendicular) to the substrate 110, and a second opening 100T2 arranged in the first opening 100T1, penetrating at least some of the active layer 160, the second gate insulating layer 154, and the second gate electrode 144 sequentially stacked on the first electrode 122 and being extended in the third direction Z.

The first opening 100T1 shown in FIG. 9 and FIG. 10 corresponds (e.g., substantially corresponds) to the opening 100T described with reference to FIG. 4, so no descriptions thereof will be provided and the second opening 100T2 will now be generally described in more detail.

Regarding the thin-film transistor 100_3 according to one or more embodiments shown in FIG. 9, the second opening 100T2 may be arranged in the first opening 100T1 defined by the first gate insulating layer 152, the second electrode 124, and the first electrode 122.

In more detail, the second opening 100T2 may penetrate the second gate electrode 144 arranged in the first opening 100T1 and may be extended in the third direction Z that is normal (e.g., perpendicular) to the substrate 110. The width of the second opening 100T2 may be less than the width of the first opening 100T1. Hence, the circumference of the external wall of the second opening 100T2 may be surrounded by the internal wall of the first opening 100T1. For example, the internal wall of the first opening 100T1 may be around the circumference of the external wall of the second opening 100T2.

The second opening 100T2 may be defined by the second gate insulating layer 154 and the second gate electrode 144. Differing from one or more embodiments show in FIG. 4, wherein the second gate electrode 144 arranged in the opening 100 (see “100” in FIG. 4) defines the gap region 144G, in the present embodiment, the second gate electrode 144 arranged in the first opening 100T1 may define the second opening 100T2. For example, the second opening 100T2 may be arranged on the bottom surface of the first opening 100T1, the bottom surface may be defined by the second gate insulating layer 154 being extended in the first direction X that is parallel to the substrate 110, and the internal wall may be defined by the second gate electrode 144 arranged on the internal wall of the first opening 100T1.

Regarding the thin-film transistor 100_4 according to one or more embodiments shown in FIG. 10, differing from the thin-film transistor 100_3 according to one or more embodiments shown in FIG. 9, the second opening 100T2 may penetrate the second gate electrode 144, the second gate insulating layer 154, and the active layer 160 arranged in the first opening 100T1.

In one or more embodiments, the second opening 100T2 may be defined by the first electrode 122, the second gate electrode 144, the second gate insulating layer 154, and the active layer 160. For example, regarding the second opening 100T2, the bottom surface may be defined by the upper surface of the first electrode 122 configuring the bottom surface of the first opening 100T1, and the internal wall may be defined by the first horizontal portion 160H1, the second gate insulating layer 154, and the second gate electrode 144 of the active layer 160 sequentially stacked on the first electrode 122 in the first opening 100T1. For example, the lateral surface of the first horizontal portion 160H1 of the active layer 160, the lateral surface of the second gate insulating layer 154, and the lateral surface of the second gate electrode 144 may be arranged on the same (e.g., substantially the same) boundary in the first opening 100T1 to configure the internal wall of the second opening 100T2. Hence, a portion of the upper surface of the first electrode 122 defining the bottom surface of the first opening 100T1 may be exposed by the second opening 100T2.

The thin-film transistors 100_3 and 100_4 according to one or more embodiments shown in FIG. 9 and FIG. 10 may have the same (e.g., substantially the same) effect as the thin-film transistor 100 according to one or more embodiments. As the thin-film transistors 100_3 and 100_4 according to one or more embodiments shown in FIG. 9 and FIG. 10 are arranged to overlap the first electrode 122 in the normal (e.g., perpendicular) direction and further include the second opening 100T2 penetrating the second gate electrode 144, the area of the second gate electrode 144 overlapping the first electrode 122 in the normal (e.g., perpendicular) direction may be minimized or reduced and parasitic capacitance between the first electrode 122 and the second gate electrode 144 may be reduced.

At least one of the transistors T1, T2, T3, T4, T5, T6, and T7 described with reference to FIG. 3 may have a structure of one of the thin-film transistors 100, 100_1, 100_2, 100_3, and 100_4 according to one or more embodiments shown in FIG. 4 to FIG. 10.

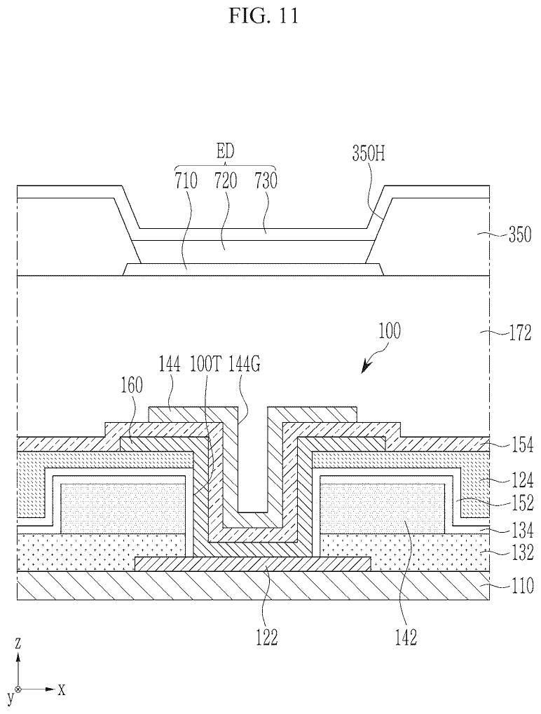

FIG. 11 shows a cross-sectional view of a display device including a thin-film transistor according to one or more embodiments.

As shown in FIG. 11, the display device may include a thin-film transistor 100. FIG. 11 shows that the display device includes the thin-film transistor 100 according to one or more embodiments shown in FIG. 4, which is not limited thereto, and the thin-film transistor included by the display device may be modifiable in many ways. For example, the display device may include one of the thin-film transistors 100_1, 100_2, 100_3, and 100_4 shown in FIG. 7 to FIG. 10. For example, the display device may include at least one of the thin-film transistors 100, 100_1, 100_2, 100_3, or 100_4 shown in FIG. 4 to FIG. 10.

The display device according to one or more embodiments will be assumed to include the thin-film transistor 100 shown in FIG. 4, and the above description on the thin-film transistor 100 may be identically (e.g., substantially identically) applied so it will not be provided.

The display device may include a thin-film transistor 100, a passivation layer 172 for covering the thin-film transistor 100, a pixel electrode 710 arranged on the passivation layer 172, a pixel defining film 350 arranged on the pixel electrode 710 and including a pixel opening 350H, a light emitting member 720 sequentially stacked on the pixel electrode 710, and a common electrode 730.

In more detail, the passivation layer 172 arranged on the thin-film transistor 100 may cover the thin-film transistor 100. The passivation layer 172 may fill the gap region 144G defined by the second gate electrode 144 of the thin-film transistor 100.

The pixel electrode 710 is arranged on the passivation layer 172, and the pixel electrode 710 may include a transparent conductive material such as indium tin oxide (ITO), indium zinc oxide (IZO), zinc oxide (ZnO) or indium oxide (In₂O₃), and a reflective metal such as lithium (Li), calcium (Ca), lithium fluoride/calcium (LiF/Ca), lithium fluoride/aluminum (LiF/AI), aluminum (AI), silver (Ag), magnesium (Mg), or gold (Au).

In one or more embodiments, the pixel electrode 710 may be electrically connected to the first electrode 122 and/or the second electrode 124 of the thin-film transistor 100 and may be an anode of the light emitting device ED.

The pixel defining film 350 may be arranged on the passivation layer 172 and an edge of the pixel electrode 710. The pixel defining film 350 may define the pixel opening 350H overlapping the pixel electrode 710. The pixel opening 350H may be arranged to overlap a portion of the pixel electrode 710.

The pixel defining film 350 may include resin such as polyacrylics or polyimides and a silica-based inorganic material.

The light emitting member 720 may be arranged on the first pixel electrode 710 overlapping the pixel opening 350H of the pixel defining film 350 in the third direction Z that is the normal (e.g., perpendicular) direction.

The light emitting member 720 may include layers including at least one of the light emitting layer, the hole injection layer (HIL), the hole transport layer (HTL), the electron transport layer (ETL), or the electron injection layer (EIL).

The light emitting layer may be an organic material or an inorganic material. When the light emitting member 720 includes all of them, the hole injection layer (HIL) may be arranged on the pixel electrode 710 that is the anode, and the hole transport layer (HTL), the light emitting layer, the electron transport layer (ETL), and the electron injection layer (EIL) may be sequentially stacked thereon.

The common electrode 730 may be arranged on the pixel defining film 350 and the light emitting member 720.

The common electrode 730 may include a transparent conductive material such as indium tin oxide (ITO), indium zinc oxide (IZO), zinc oxide (ZnO) or indium oxide (In₂O₃), and a reflective metal such as lithium (Li), calcium (Ca), lithium fluoride/calcium (LiF/Ca), lithium fluoride/aluminum (LiF/AI), aluminum (AI), silver (Ag), magnesium (Mg), or gold (Au). The common electrode 730 may be a cathode of the light emitting device ED.

The pixel electrode 710, the light emitting member 720, and the common electrode 730 may configure the light emitting device ED.

As the display device according to one or more embodiments includes the thin-film transistor with improved efficiency of power consumption by improving carrier mobility, adjustability of threshold voltage, and switching speed, high resolution may be realized, and the display device with improved electric characteristics may be provided.

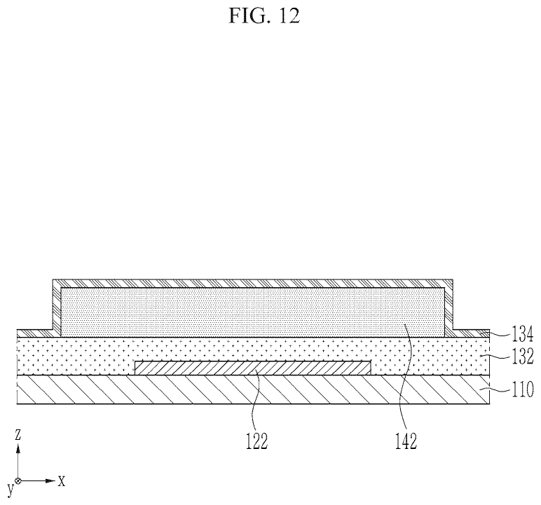

A method for manufacturing an image sensor will now be described in more detail with reference to FIG. 12 to FIG. 18. In one or more embodiments given herein, the same reference numerals are used for the same configuration as the previously described embodiments, and duplicate explanations may not be provided or may be simplified, with the differences being mainly described.

FIG. 12 to FIG. 18 show sequential cross-sectional views of a method for manufacturing a thin-film transistor according to one or more embodiments.

Referring to FIG. 12, a conductive material (e.g., electron conductor) such as a metal may be stacked on the substrate 110 by a sputtering process, and the conductive material (e.g., electron conductor) may be patterned, and the first electrode 122 may be formed at approximately the center of the substrate 110. The patterning method may use photolithography including exposure using a photomask.

An insulating material may be stacked on the first substrate 110 and the first electrode 122 to form a first buffer layer 132 by using a deposition process such as chemical vapor deposition (CVD).

Conductive material (e.g., electron conductor) such as a metal may be stacked on the first buffer layer 132, and the conductive material (e.g., electron conductor) may be patterned to form the first gate electrode 142. The method for patterning the first gate electrode 142 may be the same (e.g., substantially the same) as or similar to the method for patterning the first electrode 122.

The second buffer layer 134 may be formed by stacking an insulating material on the first gate electrode 142. The second buffer layer 134 may be conformally formed along the surface of the first buffer layer 132 and the surface of the first gate electrode 142.

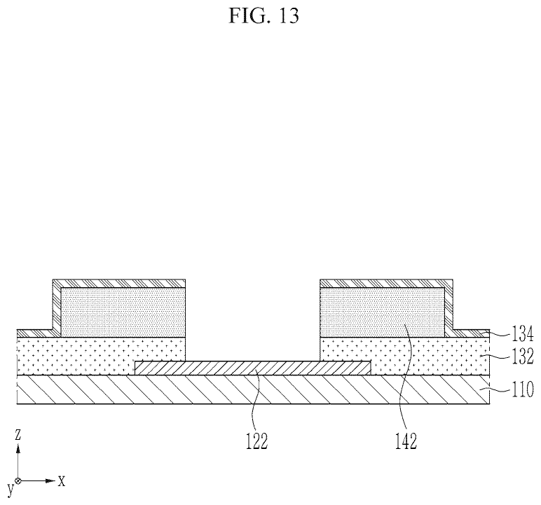

Referring to FIG. 13, a portion of the first electrode 122 may be exposed by continuously patterning the second buffer layer 134, the first gate electrode 142, and the first buffer layer 132.

The lateral surface of the second buffer layer 134 exposing the first electrode 122, the lateral surface of the first gate electrode 142, and the lateral surface of the first buffer layer 132 may be arranged on the same (e.g., substantially the same) boundary.

The second buffer layer 134, the first gate electrode 142, and the first buffer layer 132 may use photolithography including exposure using a photomask. The etching method may continuously etch by using, for example, a dry etching process. The materials for etching the first buffer layer 132 and the second buffer layer 134 may be the same, and the material for etching the first gate electrode 142 may be different. However, this is an example, and the etching method and the etching material may be modifiable in many ways. For example, the second buffer layer 134, the first gate electrode 142, and the first buffer layer 132 may be concurrently (e.g., simultaneously) patterned.

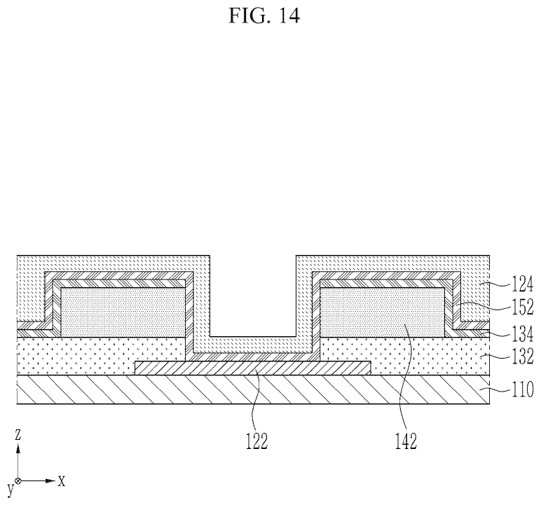

Referring to FIG. 14, an insulating material and a conductive material (e.g., electron conductor) such as a metal may be sequentially stacked on the patterned second buffer layer 134, the first gate electrode 142, and the first buffer layer 132, and the first electrode 122 exposed to sequentially form the first gate insulating layer 152 and the second electrode 124.

The first gate insulating layer 152 may be conformally formed along the patterned second buffer layer 134, the first gate electrode 142, the first buffer layer 132, and the exposed surface of the first electrode 122.

The second electrode 124 may be formed along the shape of the surface of the first gate insulating layer 152. The second electrode 124 may cover the first gate insulating layer 152.

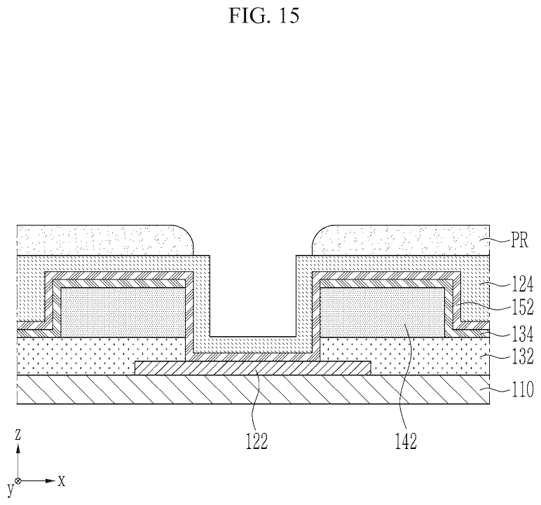

Referring to FIG. 15, a photoresist pattern PR may be formed on the second electrode 124. The photoresist pattern PR may be formed by stacking a photosensitive material such as photoresist, and exposing the photosensitive material layer by use of a photomask.

A portion of the second electrode 124 may be exposed by the photoresist pattern PR. An end of the photoresist pattern PR may be arranged on the same (e.g., substantially the same) boundary as the lateral surface of the first gate insulating layer 152 being extended along the second buffer layer 134, the first gate electrode 142, and the first buffer layer 132 arranged on the same (e.g., substantially the same) boundary on the first electrode 122.

Accordingly, the second electrode 124 protruding further than the end of the photoresist pattern PR and overlapping the first electrode 122 in the normal (e.g., perpendicular) third direction Z may be exposed by the photoresist pattern PR.

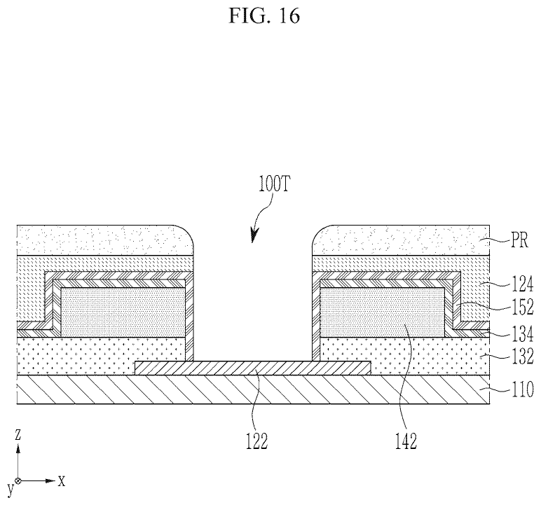

Referring to FIG. 16 together with FIG. 15, a photoresist pattern PR may be used as an etch mask to form the opening 100T for exposing a portion of the first electrode 122 as the second electrode 124 and the first gate insulating layer 152 are continuously etched.

In more detail, a portion of the second electrode 124 and a portion of the first gate insulating layer 152 not overlapping the photoresist pattern PR in the third direction Z that is the normal (e.g., perpendicular) direction may be continuously etched. The etching method may, for example, use a dry etching process.

The materials for etching the second electrode 124 and the first gate insulating layer 152 may be different from each other. However, this is an example, and the etching method and the etching material may be modifiable in many ways. For example, the second electrode 124 and the first gate insulating layer 152 may be concurrently (e.g., simultaneously) etched with the same etching material.

When a portion of the second electrode 124 and a portion of the first gate insulating layer 152 are removed, the exposed upper surface of the first electrode 122 may configure the bottom surface of the opening 100T, and the lateral surface of the second electrode 124 and the lateral surface of the first gate insulating layer 152 arranged on the same (e.g., substantially the same) boundary as the end of the photoresist pattern PR on the first electrode 122 may configure the internal wall of the opening 100T.

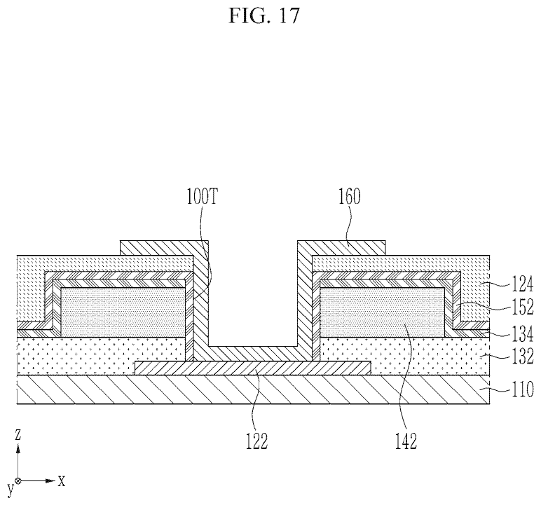

Referring to FIG. 17 together with FIG. 16, the photoresist pattern PR may be removed, and an active layer 160 may be formed along the upper surface of the second electrode 124 around (e.g., surrounding) the opening 100T, and the internal wall and the bottom surface of the opening 100T.

For example, the oxide semiconductor material may be conformally stacked along the upper surface of the second electrode 124 and the internal wall and the bottom surface of the opening 100T, and the oxide semiconductor material may be patterned to form the active layer 160. The oxide semiconductor material may be formed by using, for example, a sputtering or deposition process. The patterning method may use the same (e.g., substantially the same) or a similar method as the above-described method.

The active layer 160 may be conformally formed along the upper surface of the first electrode 122 configuring the bottom surface of the opening 100T, the lateral surface of the first gate insulating layer 152 and the lateral surface of the second electrode 124 configuring the internal wall of the opening 100T, and a portion of the upper surface of the second electrode 124 around (e.g., surrounding) the opening 100T. For example, the active layer 160 may be formed to have a set or predetermined thickness.

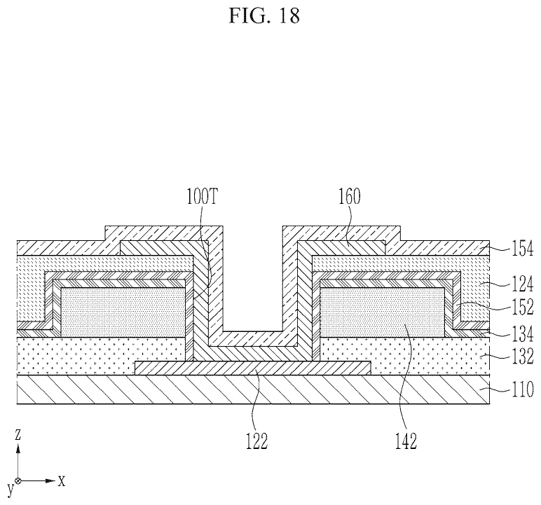

Referring to FIG. 18, the second gate insulating layer 154 may be formed by stacking an insulating material on the second electrode 124 and the active layer 160. The second gate insulating layer 154 may be conformally formed along the surface of the active layer 160 and the surface of the second electrode 124.

Referring to FIG. 4 together with FIG. 18, the conductive material (e.g., electron conductor) such as a metal may be stacked on the second gate insulating layer 154, and the conductive material may be patterned to form the second gate electrode 144. The method for patterning the second gate electrode 144 may be the same (e.g., substantially the same) as or similar to the method for patterning the first gate electrode 142.

The second gate electrode 144 may be conformally formed along the surface of the second gate insulating layer 154. For example, a portion of the second gate electrode 144 may be formed along the surface of the second gate insulating layer 154 arranged on the bottom surface and the internal wall of the opening 100T, and the remaining portion thereof may be formed along the upper surface of the second electrode 124 around (e.g., surrounding) the opening 100T. The second gate electrode 144 formed along the surface of the second gate insulating layer 154 may define the gap region 144G in the opening 100T.

Accordingly, the first gate electrode 142 may be arranged on one side of the active layer 160 in the first direction X, being extended in the third direction Z that is the normal (e.g., perpendicular) direction along the internal wall of the opening 100T, and the second gate electrode 144 may be arranged on the other side (e.g., opposite side) thereof.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A display device according to an embodiment may be applied to various electronic devices. An electronic device according to an embodiment may include the display device, and may further include modules or devices having additional functions other than the display device.

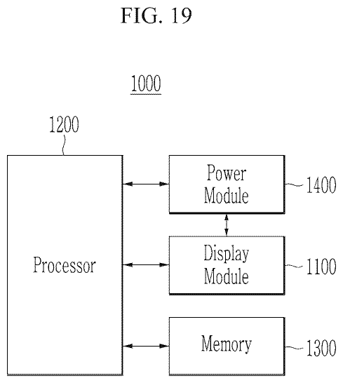

FIG. 19 is a block diagram of an electronic device according to an embodiment. Referring to FIG. 19, the electronic device 1000 according to an embodiment may include a display module 1100, a processor 1200, a memory 1300, and a power module 1400.

The processor 1200 may include at least one of a central processing unit (CPU), an application processor (AP), a graphic processing unit (GPU), a communication processor (CP), an image signal processor (ISP), and a controller.

The memory 1300 may store data information necessary for operations of the processor 1200 or the display module 1100. When the processor 1200 executes an application stored in the memory 1300, video data signals and/or input control signals are transmitted to the display module 1100, and the display module 1100 can process the received signals to output video information through the display screen.

The power module 1400 may include a power supply module such as a power adapter or battery device, and a power conversion module that converts the power supplied by the power supply module to generate the power necessary for the operation of the electronic device 1000.

At least one of components of the electronic device 1000 may be included within the display device according to the above-described embodiments. Additionally, some of the individual modules that are functionally included within a single module may be incorporated into the display device, while others may be provided separately from the display device. For example, the display device may include the display module 1100, while the processor 1200, memory 1300, and power module 1400 may be provided in a form of other devices within the electronic device 1000 that are not part of the display device.

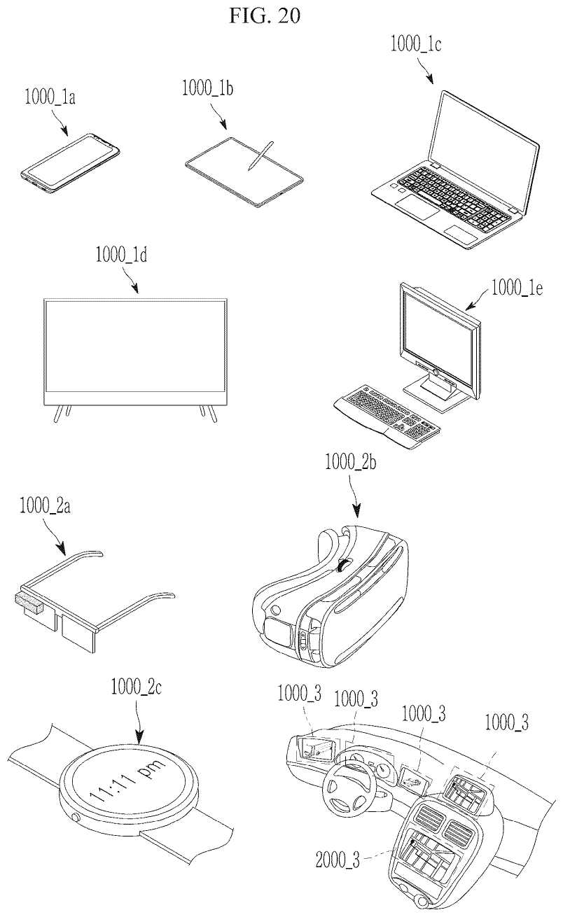

FIG. 20 shows schematic diagrams of electronic devices according to various embodiments.

Referring to FIG. 20, various electronic devices with the display device according to the embodiments may include not only image display electronic devices such as smartphones 1000_1a, tablet PCs 1000_1b, laptops 1000_1c, TVs 1000_1d, desktop monitors 1000_1e, but also wearable electronic devices with display modules such as smart glasses 1000_2a, head-mounted displays 1000_2b, smart watches 1000_2c, as well as automotive electronic devices with display modules 1000_3 such as those placed on car dashboards, center fascias, CID (Center Information Display), room mirror displays, and so on.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The foregoing is illustrative of one or more embodiments of the present disclosure, and is not to be construed as limiting thereof. Although a few embodiments have been described with reference to the drawings, those skilled in the art will readily appreciate that many variations and modifications may be made therein without departing from the spirit and scope of the present disclosure as defined in the appended claims, and equivalents thereof.

### REFERENCE NUMERALS

100: thin film transistor
110: substrate
122: first electrode
124: second electrode
126: first transparent electrode
128: second transparent electrode
132: first buffer layer
134: second buffer layer
142: first gate electrode
144: second gate electrode
152: first gate insulating layer
154: second gate insulating layer
160: active layer

What is claimed is:

1. A thin-film transistor comprising:
a substrate;
a first electrode on the substrate;
a first gate electrode on the first electrode;
a first buffer layer between the first electrode and the first gate electrode;
a first gate insulating layer on the first gate electrode;
a second electrode on the first gate insulating layer;
an active layer being extended in a horizontal direction along a bottom surface and in a normal direction along an internal wall of a first opening penetrating the first gate electrode, the first buffer layer, the first gate insulating layer, and the second electrode, and connected to the first electrode and the second electrode;
a second gate electrode being extended along a surface of the active layer; and
a second gate insulating layer between the active layer and the second gate electrode,
wherein the active layer being extended in the normal direction along the internal wall of the first opening overlaps the first gate electrode and the second gate electrode in the horizontal direction.

2. The thin-film transistor of claim 1, wherein
the first opening comprises
a bottom surface defined by an upper surface of the first electrode, and
an internal wall defined by the first gate insulating layer and the second electrode, and
the active layer comprises
a first horizontal portion being extended in the horizontal direction along the bottom surface of the first opening,
a normal portion being extended in the normal direction along the internal wall of the first opening, and
a second horizontal portion being extended in the horizontal direction along an upper surface of the second electrode.

3. The thin-film transistor of claim 2, further comprising
a second buffer layer between the first gate electrode and the first gate insulating layer,
wherein the first buffer layer and the second buffer layer surround the first opening.

4. The thin-film transistor of claim 3, wherein
the normal portion of the active layer comprises
a first portion overlapping the first buffer layer in the horizontal direction,
a second portion overlapping the first gate electrode in the horizontal direction and not overlapping the second gate electrode in the horizontal direction,
a third portion overlapping the first gate electrode and the second gate electrode in the horizontal direction, and
a fourth portion overlapping the first gate insulating layer and the second buffer layer in the horizontal direction,
the first portion, the second portion, the third portion, and the fourth portion are continuously arranged in the normal direction, and
a thickness of the third portion is greater than each of the thickness of the first portion, the thickness of the second portion, and the thickness of the fourth portion.

5. The thin-film transistor of claim 4, wherein
a sum of the thickness of the first portion, the thickness of the second portion, and the thickness of the fourth portion is less than the thickness of the third portion.

6. The thin-film transistor of claim 2, wherein
the thicknesses of the first horizontal portion, the normal portion, and the second horizontal portion of the active layer are each independently substantially equal to each other.

7. The thin-film transistor of claim 2, wherein
the active layer comprises an oxide semiconductor material, and
the oxide semiconductor material comprises at least one of In, Ga, Zn, or Sn.

8. The thin-film transistor of claim 7, wherein
the active layer comprises
a first active layer being extended along the upper surface of the second electrode and the bottom surface and the internal wall of the first opening, and
a second active layer between the first active layer and the second gate insulating layer,
a first material included in the first active layer and the first material included in the second active layer have different composition ratios, and
the first material is at least one of In, Ga, Zn, or Sn.

9. The thin-film transistor of claim 8, wherein
the first active layer and the second active layer have different thicknesses.

10. The thin-film transistor of claim 2, further comprising
a first transparent electrode between the first electrode and the first horizontal portion of the active layer, and
a second transparent electrode between the second electrode and the second horizontal portion of the active layer.

11. The thin-film transistor of claim 10, wherein
the first transparent electrode covers the upper surface of the first electrode, and
the second transparent electrode covers a portion of the upper surface of the second electrode.

12. The thin-film transistor of claim 2, wherein
the thin-film transistor comprises a second opening penetrating the second gate electrode in the first opening and defined by the upper surface of the second gate insulating layer and the lateral surface of the second gate electrode.

13. The thin-film transistor of claim 2, wherein
the thin-film transistor comprises a second opening penetrating the first horizontal portion of the active layer, the second gate insulating layer, and the second gate electrode in the first opening, and defined by the upper surface of the first electrode, a lateral surface of the first horizontal portion of the active layer, a lateral surface of the second gate insulating layer, and a lateral surface of the second gate electrode.

14. The thin-film transistor of claim 1, wherein
the width of the first opening is less than the width of the first electrode.

15. The thin-film transistor of claim 14, wherein
the width of the first opening is in a range of about 1.5 μm to about 3 μm.

16. The thin-film transistor of claim 1, wherein
the first opening has a circular, oval, or polygonal shape in a plan view.

17. A method comprising:
forming a first electrode on a substrate;
forming a first buffer layer on the first electrode;
forming a first gate electrode on the first buffer layer;
removing a portion of the first gate electrode and a portion of the first buffer layer to expose the first electrode;
sequentially forming a first gate insulating layer and a second electrode on the first electrode, the first gate electrode, and the first buffer layer exposed by the first gate electrode and the first buffer layer;
forming an opening for exposing the first electrode by removing a portion of the first gate insulating layer and a portion of the second electrode;
forming an active layer being extended along an upper surface of the second electrode and a bottom surface and an internal wall of the opening;
forming a second gate insulating layer being extended along a surface of the active layer and the upper surface of the second electrode; and
forming a second gate electrode being extended along a surface of the second gate insulating layer,
wherein the method is a method for manufacturing a thin-film transistor.

18. The method of claim 17, further comprising
forming a second buffer layer on the first gate electrode before removing a portion of the first gate electrode and a portion of the first buffer layer,
wherein the removing of a portion of the first gate electrode and a portion of the first buffer layer comprises
removing a portion of the first buffer layer and a portion of the second buffer layer together with a portion of the first gate electrode and a portion of the first buffer layer.

19. The method of claim 17, wherein
the opening comprises
a bottom surface defined by the upper surface of the first electrode, and
an internal wall defined by the first gate insulating layer and the second electrode.

20. An electronic device comprising:
a thin-film transistor comprising:
a substrate;
a first electrode on the substrate;
a first gate electrode on the first electrode;
a first buffer layer between the first electrode and the first gate electrode;
a first gate insulating layer on the first gate electrode;
a second electrode on the first gate insulating layer;
an active layer being extended in a horizontal direction along a bottom surface and in a normal direction along an internal wall of a first opening penetrating the first gate electrode, the first buffer layer, the first gate insulating layer, and the second electrode, and connected to the first electrode and the second electrode;
a second gate electrode being extended along a surface of the active layer; and
a second gate insulating layer between the active layer and the second gate electrode,
wherein the active layer being extended in the normal direction along the internal wall of the first opening overlaps the first gate electrode and the second gate electrode in the horizontal direction.
